(19) United States
(12) Patent Application Publication
(10) Pub. No.: US 2025/0294726 A1
(43) Pub. Date: Sep. 18, 2025

(54) SEMICONDUCTOR DEVICE

(71) Applicant: Samsung Electronics Co., Ltd., Suwon-si (KR)

(72) Inventors: Jaeho KIM, Suwon-si (KR); Jinbum KIM, Suwon-si (KR); Kyeonggyu LEE, Suwon-si (KR); Sunguk JANG, Suwon-si (KR); Wonhee CHOI, Suwon-si (KR)

(73) Assignee: Samsung Electronics Co., Ltd., Suwon-si (KR)

(21) Appl. No.: 19/002,092

(22) Filed: Dec. 26, 2024

(30) Foreign Application Priority Data
Mar. 15, 2024 (KR) 10-2024-0036461

(51) Int. Cl. H10B 12/00

(52) U.S. Cl. CPC H10B 12/485; H10B 12/0335; H10B 12/315

(57) ABSTRACT

Various example embodiments of various example embodiments provide a semiconductor device including a substrate, a bit line on the substrate, extending in a first direction, including a first conductive pattern and a second conductive pattern on the first conductive pattern, word lines extending on the bit line in a second direction intersecting the first direction; and active patterns including a channel portion between the word lines on the bit line, and a contact portion extending from a lower surface of the channel portion to penetrate the second conductive pattern and electrically connected between the first conductive pattern and the channel portion.

### CROSS-REFERENCE TO RELATED APPLICATION

This application claims priority to and the benefit of Korean Patent Application No. 10-2024-0036461 filed in the Korean Intellectual Property Office on Mar. 15, 2024, the entire contents of which are incorporated herein by reference.

### BACKGROUND

Various example embodiments of the inventive concepts relate to a semiconductor device.

It is desired to increase the integration of semiconductor memory devices in order to meet the excellent performance and low price desired by consumers. In the case of semiconductor memory devices, an increased degree of integration is particularly desired because the degree of integration is an important factor in determining the price of the product.

In the case of two-dimensional or planar semiconductor memory devices, the degree of integration is mainly determined by the area occupied by a unit memory cell, and is therefore greatly affected by the level of fine pattern formation technology. However, since ultra-high-priced equipment is required to refine patterns, the degree of integration of two-dimensional semiconductor memory devices is increasing but is still limited.

Accordingly, semiconductor memory devices including vertical channel transistors whose channels extend in a vertical direction have been proposed.

### SUMMARY

Various example embodiments attempt to provide a semiconductor device with improved reliability and productivity.

Various example embodiments provide a semiconductor device including a substrate, a bit line on the substrate, extending in a first direction, including a first conductive pattern and a second conductive pattern on the first conductive pattern, word lines extending on the bit line in a second direction intersecting the first direction; and active patterns including a channel portion between the word lines on the bit line, and a contact portion extending from a lower surface of the channel portion to penetrate the second conductive pattern and electrically connected between the first conductive pattern and the channel portion.

Various example embodiments provide a semiconductor device including a substrate, a bit line on the substrate, extending in a first direction, including a first conductive pattern and a second conductive pattern on the first conductive pattern, word lines extending on the bit line in a second direction intersecting the first direction, and active patterns including a channel portion between the word lines on the bit line and a contact portion extending from a lower surface of the channel portion to penetrate the second conductive pattern. The second conductive pattern and the contact portion include silicon doped with impurities, and an activation concentration of impurities doped into the contact portion is greater than that of impurities doped into the second conductive pattern.

Various example embodiments provide a semiconductor device including a substrate, a bit line including a first conductive pattern on the substrate extending in a first direction, a second conductive pattern on the first conductive pattern, and a third conductive pattern between the first conductive pattern and the second conductive pattern, word lines extending on the bit line in a second direction intersecting the first direction, active patterns including a channel portion between the word lines on the bit line, and a contact portion extending from a lower surface of the channel portion, and a back gate electrode extending in the second direction on the bit line and between the active patterns. The contact portion includes a first portion penetrating the second conductive pattern and including a semiconductor material doped with impurities, a second portion between the first portion and the first conductive pattern and penetrating the third conductive pattern, the first portion and the second conductive pattern include a semiconductor material doped impurities, and an activation concentration of impurities doped into the first portion is greater than that of impurities doped into the second conductive pattern.

According to various example embodiments, it is possible to improve the reliability of the semiconductor device.

### BRIEF DESCRIPTION OF THE DRAWINGS

FIG. 1 illustrates a top plan view of a semiconductor device according to various example embodiments.

FIG. 2 illustrates a cross-sectional view taken along line A-A′ of FIG. 1.

FIG. 3 illustrates a cross-sectional view taken along line B-B′ and line C-C′ of FIG. 1.

FIG. 4 illustrates a partial enlarged view of area “P” of FIG. 2.

FIG. 5 to FIG. 9 illustrate partially enlarged views corresponding to area “P” of FIG. 4 illustrating a semiconductor device according to some example embodiments.

FIG. 10 illustrates a cross-sectional view taken along line A-A′ of FIG. 1, illustrating a method of manufacturing a semiconductor device according to various example embodiments.

FIG. 11 to FIG. 16 illustrate partially enlarged views corresponding to area “Q” of FIG. 10, illustrating a method of manufacturing a semiconductor device according to various example embodiments.

FIG. 17 to FIG. 19 illustrate partially enlarged views corresponding to area “Q” of FIG. 10, illustrating a method of manufacturing a semiconductor device according to some example embodiments.

FIG. 20 to FIG. 23 illustrates cross-sectional views taken along line A-A′ of FIG. 1, illustrating a method of manufacturing a semiconductor device according to various example embodiments.

### DETAILED DESCRIPTION

Various example embodiments will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the various example embodiments, parts or portions that are irrelevant to the description are omitted, and identical or similar constituent elements throughout the specification are denoted by the same reference numerals.

Furthermore, in the drawings, the size and thickness of each element are arbitrarily illustrated for ease of description, and various example embodiments are not necessarily limited to those illustrated in the drawings. In the drawings, the thicknesses of layers, films, panels, regions, areas, etc., may be exaggerated for clarity. In the drawings, for ease of description, the thicknesses of some layers and areas may be exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

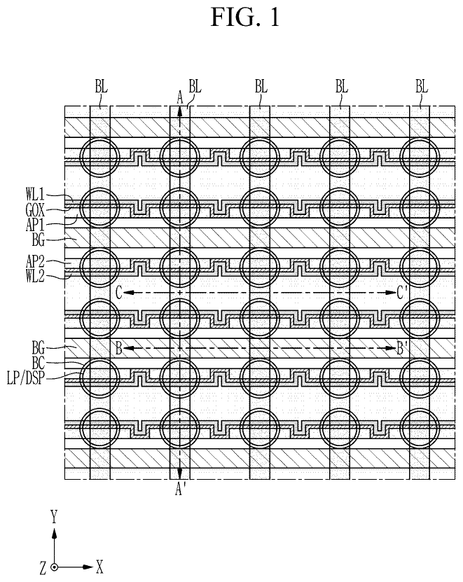

Hereinafter, a semiconductor device according to various example embodiments will be described with reference to FIG. 1 to FIG. 4.

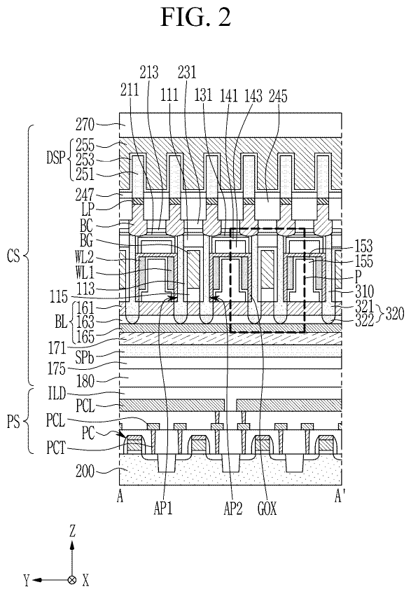

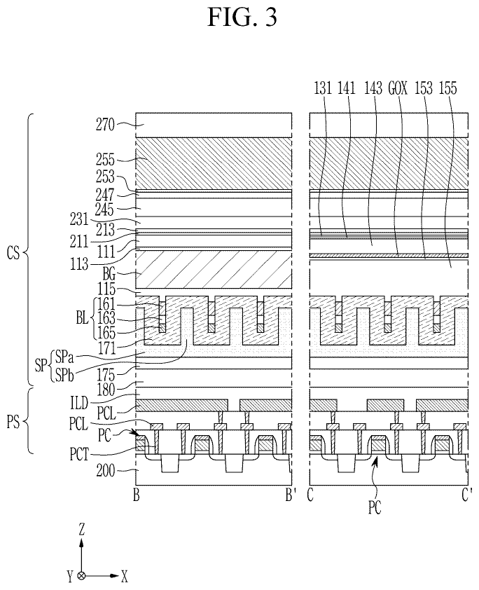

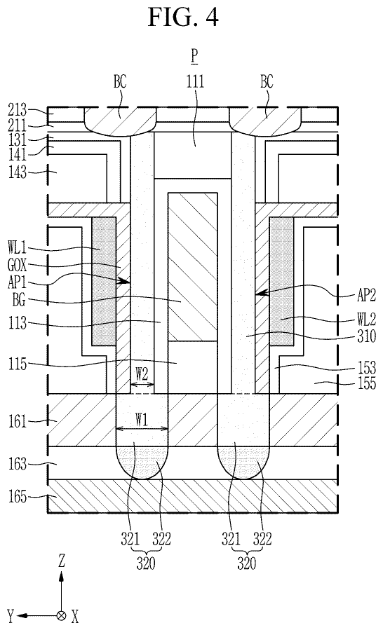

FIG. 1 illustrates a top plan view of a semiconductor device according to various example embodiments. FIG. 2 illustrates a cross-sectional view taken along line A-A′ of FIG. 1. FIG. 3 illustrates a cross-sectional view taken along line B-B′ and line C-C′ of FIG. 1. FIG. 4 illustrates a partial enlarged view of area “P” of FIG. 2.

A semiconductor device according to various example embodiments may include a substrate 200, a peripheral circuit structure PS, and a cell array structure CS connected to the peripheral circuit structure PS.

The substrate 200 may include a cell array area and a peripheral connection area defined around the cell array area. Memory cells may be disposed on the substrate 200 of the cell array area. Here, the memory cells of the semiconductor device according to the embodiment may include a vertical channel transistor (VCT). The peripheral connection area may be disposed adjacent to the cell array area and may surround the cell array area. The disposition relationship between the cell array area and the peripheral connection area may be variously changed.

Active patterns AP1 and AP2, bit lines BL, word lines WL1 and WL2, landing pads LP, data storage patterns DSP, and the like are disposed in the cell array area of the substrate 200, and a separation insulating pattern, a bit line contact plug electrically connected to the bit line, a shielding pattern contact plug, and the like may be disposed in the peripheral connection area.

The substrate 200 may be a single crystal silicon substrate 200 or may include other materials, for example, silicon germanium, indium antimony, lead tellurium compound, indium arsenic, indium phosphide, gallium arsenic, or gallium antimony, but example embodiments are not limited thereto.

The peripheral circuit structure PS may be disposed on the substrate 200. The peripheral circuit structure PS may be disposed between the substrate 200 and the cell array structure CS. The peripheral circuit structure PS may be disposed across the cell array area and the peripheral connection area of the substrate 200.

The peripheral circuit structure PS may be disposed between the substrate 200 and a flat insulating layer 180 of the cell array structure CS. The peripheral circuit structure PS may include core and peripheral circuits PC disposed on the substrate 200, peripheral circuit insulating layers ILD covering the core and peripheral circuits PC and disposed between the substrate 200 and the flat insulating layer 180, and peripheral metal structures PCT and PCL disposed in the peripheral circuit insulating layers ILD.

The core and peripheral circuits PC may include row and column decoders, a sense amplifier, a control logic, and the like. For example, the core and peripheral circuits PC may include NMOS and PMOS transistors integrated on the substrate 200. However, various example embodiments are not limited thereto, and the type of transistor of the peripheral circuit PC disposed on the substrate 200 may be variously changed according to the design disposition of the semiconductor device.

The peripheral circuit insulating layer ILD may cover the core and the peripheral circuits PC and the peripheral metal structures PCL and PCT. The peripheral circuit insulating layer ILD may include multi-layered insulating layers.

The peripheral circuit insulating layer ILD may include an insulating material. For example, it may include a silicon oxide, a silicon nitride, a silicon oxynitride, and/or a low dielectric material. However, example embodiments are not limited thereto,

The peripheral metal structures PCT and PCL may include at least two or more metal patterns PCL and the metal plugs PCT connected to the metal patterns PCL.

As described above, the cell array structure CS may include memory cells including a vertical channel transistor (VCT). Specifically, the cell array structure CS may include a vertical channel transistor (VCT) as cell transistors of each memory cell and a capacitor as a data storage device of each memory cell. The vertical channel transistor may refer to a structure in which the channel length extends in a direction perpendicular to the upper surface of the substrate 200.

The cell array structure CS of the semiconductor device according to the embodiment may include bit lines BL, a spacer insulating layer 171, a shielding pattern SP, first and second active patterns AP1 and AP2, first and second word lines WL1 and WL2, back gate electrodes BG, and a data storage pattern DSP.

The bit lines BL may be disposed adjacent to the peripheral circuit structure PS. For example, the bit lines BL may be disposed adjacent to the peripheral circuit structure PS in a third direction (Z direction), but example embodiments are not limited thereto. Accordingly, since the bit lines BL are disposed adjacent to the peripheral circuit structure PS, an electrical connection path between the bit lines BL and the core and peripheral circuits PC may be reduced.

A plurality of bit lines BL may be disposed on the substrate 200 to be spaced apart from each other in a first direction (X direction). The bit lines BL may extend parallel to each other in a second direction (Y direction) that intersects the first direction (X direction). The plurality of bit lines BL may be electrically connected to the first and second active patterns AP1 and AP2. For example, the plurality of bit lines BL may be electrically connected to each of the first and second active patterns AP1 and AP2 through a contact portion 320, which will be described later.

Each of the bit lines BL of the semiconductor device according to various example embodiments may include a first conductive pattern 165, a third conductive pattern 163, and a second conductive pattern 161 sequentially stacked.

The first conductive pattern 165 may be disposed on the substrate 200. For example, the first conductive pattern 165 may be disposed on the spacer insulating layer 171 to be described later, but example embodiments are not limited thereto. The first conductive pattern 165 may extend in the second direction (Y direction). The first conductive pattern 165 may be disposed in the first direction (X direction).

In various example embodiments, the first conductive pattern 165 may include a conductive material. For example, the first conductive pattern 165 may include a conductive metal nitride (for example, a titanium nitride, a tantalum, or the like), a metal (for example, tungsten, titanium, tantalum, or the like), or a combination thereof. However, example embodiments are not limited thereto.

The second conductive pattern 161 may be disposed on the first conductive pattern 165. For example, the second conductive pattern 161 may be disposed between the first conductive pattern 165 and the first and second active patterns AP1 and AP2 to be described later. The second conductive pattern 161 may extend in the second direction (Y direction). The second conductive pattern 161 may be disposed in the first direction (X direction). The second conductive pattern 161 may completely overlap the first conductive pattern 165 in the third direction (Z direction). The upper surface of the second conductive pattern 161 may be in contact with the first and second active patterns AP1 and AP2. In addition, the second conductive pattern 161 may contact a gate insulating pattern GOX, a first gate separation pattern 153, and a second gate separation pattern 155 to be described later, but example embodiments are not limited thereto. The second conductive pattern 161 may be penetrated by the contact portion 320 of the first and second active patterns AP1 and AP2 to be described later.

In various example embodiments, the second conductive pattern 161 may include a semiconductor material doped with impurities. The semiconductor material may be silicon. For example, the second conductive pattern 161 may include amorphous silicon (a-Si) doped with impurities. Here, the impurity may include phosphorus (P), but example embodiments are not limited thereto. For example, the activation concentration of the impurity doped in the second conductive pattern 161 may be about 2×10²⁰ cm⁻³ or less, but example embodiments are not limited thereto. Here, the activation concentration may mean the concentration of an impurity that may perform a dopant function by replacing the semiconductor material element with the impurity in a semiconductor material to form a semiconductor material doped with an impurity. For example, when the second conductive pattern 161 includes silicon (Si) doped with impurities (for example, phosphorus (P)), at least some of the impurities may be substituted with the silicon element, and the others may not be substituted with the silicon element. In this case, the activation concentration of the impurities of the second conductive pattern 161 may mean the concentration of the impurities are substituted with the silicon element. In other words, it may mean the content (at %) of impurities are combined with the silicon element. Meanwhile, the activation concentration of the impurities doped in the second conductive pattern 161 may be smaller than a total concentration of the impurities doped in the second conductive pattern 161. The activation concentration of the doped impurities may be detected through secondary ion mass spectroscopy (SIMS), X-ray diffraction, or the like. Alternatively, the difference in the activation concentration of the impurities may be calculated by detecting the specific resistance of silicon.

In various example embodiments, the second conductive pattern 161 may be formed together during a process in which the contact portion 320 of the first and second active patterns AP1 and AP2, which will be described later, is formed by a selective epitaxial growth method SEG using the first and second active patterns AP1 and AP2 as a seed.

The third conductive pattern 163 may be disposed between the first conductive pattern 165 and the second conductive pattern 161. The third conductive pattern 163 may extend in the second direction (Y direction). The third conductive pattern 163 may be disposed in the first direction (X direction). The third conductive pattern 163 may completely overlap the first conductive pattern 165 and the second conductive pattern 161 in the third direction (Z direction). The third conductive pattern 163 may be penetrated by the contact portion 320 of the first and second active patterns AP1 and AP2 to be described later. The third conductive pattern 163 may include a metal-silicide material. For example, the third conductive pattern 163 may include titanium silicide, cobalt silicide, nickel silicide, or a combination thereof, but example embodiments are not limited thereto. In various example embodiments, the third conductive pattern 163 may be doped with impurities, and in this case, the activation concentration of the impurities may be within a desired (and/or alternatively predetermined) range.

In some example embodiments, the bit lines BL may include two-dimensional and three-dimensional materials. For example, they may include graphene that is a carbon-based two-dimensional material, carbon nanotube that is a three-dimensional material, or a combination thereof.

The spacer insulating layer 171 may be disposed on lower surfaces of the bit lines BL. The spacer insulating layer 171 may have substantially uniform thickness, and may be conformally disposed on the lower surfaces of the bit lines BL. For example, as illustrated in FIG. 3, the spacer insulating layer 171 may cover both side surfaces and the lower surfaces of the bit lines BL. The spacer insulating layer 171 may extend parallel to the bit lines BL in the second direction (Y direction).

The spacer insulating layer 171 may include an insulating material. For example, the spacer insulating layer 171 may include a silicon oxide film, a silicon nitride film, a silicon oxynitride film, and/or a low dielectric film. However, the material included in the spacer insulating layer 171 is not limited thereto, and may be variously changed.

The shielding pattern SP may be disposed below the spacer insulating layer 171. The shielding pattern SP may include line portions SPa respectively disposed between the bit lines BL adjacent to each other and a plate portion SPb commonly connecting the line portions SPa.

The line portions SPa of the shielding pattern SP may be disposed between the bit lines BL adjacent to each other. The line portions SPa of the shielding pattern SP may be disposed in gap areas defined by the spacer insulating layer 171 between the bit lines BL. That is, the line portions SPa of the shielding pattern SP and the side surfaces of the bit lines BL may be spaced apart from each other in the first direction (X direction) with the spacer insulating layer 171 interposed therebetween. The line portions SPa of the shielding pattern SP may extend along the second direction (Y direction).

In various example embodiments, the line portions SPa of the shielding pattern SP disposed between the bit lines BL adjacent to each other may reduce coupling capacitance due to mutual interference between the bit lines BL disposed adjacent to each other.

The plate portion SPb of the shielding pattern SP may be connected to the line portions SPa, and may be integrally formed with the line portions SPa. That is, the plate portion SPb of the shielding pattern SP may be disposed below the line portions SPa, and may connect the line portions SPa disposed between the bit lines BL adjacent to each other. The line portions SPa of the shielding pattern SP may extend from the plate portion SPb of the shielding pattern SP in the third direction (Z direction), which is a direction perpendicular to the substrate 200, and may be disposed between adjacent bit lines BL. The plate portion SPb of the shielding pattern SP may overlap the bit lines BL in the third direction (Z direction), which is a direction perpendicular to the substrate 200. However, the configuration of the line portions SPa and the plate portion SPb of the shielding pattern SP is not limited thereto, and in some example embodiments, the line portions SPa and the plate portion SPb of the shielding pattern SP may be separately configured.

The plate portion SPb of the shielding pattern SP and the lower surfaces of the bit lines BL may be spaced apart from each other in the third direction (Z direction) with the spacer insulating layer 171 interposed therebetween.

In FIG. 3, the height of the bit line BL in the third direction (Z direction) is shown to be higher than the height of the line portion SPa of the shielding pattern SPa in the third direction (Z direction), but example embodiments are not limited thereto, and the height of the bit line BL in the third direction (Z direction) may be substantially the same as the height of the line portion SPa of the shielding pattern SP in the third direction (Z direction).

The shielding pattern SP may include a conductive material. For example, it may include a metal material such as tungsten (W), titanium (Ti), nickel (Ni), cobalt (Co), or the like. As another example, the shielding pattern SP may include a conductive two-dimensional (2D) material such as graphene. However, example embodiments are not limited thereto.

The semiconductor device according to the embodiment may further include a capping insulating layer 175 and a flat insulating layer 180 disposed between the peripheral circuit structure PS and the capping insulating layer 175.

The capping insulating layer 175 may be disposed on a lower surface of the shielding pattern SP. The capping insulating layer 175 may have a substantially uniform thickness, and may cover the lower surface of the shielding pattern SP. The capping insulating layer 175 may include an insulating material. For example, the capping insulating layer 175 may include a silicon oxide film, a silicon nitride film, a silicon oxynitride film, and/or a low dielectric film.

The flat insulating layer 180 may cover a lower surface of the capping insulating layer 175, and may planarize a lower area of the cell array structure CS that is in contact with the peripheral circuit structure PS. The flat insulating layer 180 may be, for example, one of insulating materials and a silicon oxide layer formed by using a spin-on glass (SOG) technology.

The active patterns AP1 and AP2 may be disposed on the bit line BL. The first active patterns AP1 and the second active patterns AP2 may be alternately disposed in the second direction (Y direction). Here, the first active patterns AP1 may mean active patterns disposed on one side of the back gate electrode BG, and the second active patterns AP2 may mean active patterns disposed on the other side of the back gate electrode BG. In this case, the first active patterns AP1 and the second active patterns AP2 may have a symmetrical shape with respect to a central axis extending in the third direction (Z direction) in a cross-sectional view formed in the second direction (Y direction) and the third direction (Z direction).

The first active patterns AP1 may be spaced apart from each other in the first direction (X direction). For example, as illustrated in FIG. 1, the first active patterns AP1 may be spaced apart from each other at regular intervals. The second active patterns AP2 may be spaced apart from each other in the first direction (X direction). For example, as illustrated in FIG. 1, the second active patterns AP2 may be spaced apart from each other at regular intervals. The first and second active patterns AP1 and AP2 may be two-dimensionally arranged along the first direction (X direction) and the second direction (Y direction) crossing each other. At least some of the active patterns AP1 and AP2 may be in contact with the bit lines BL. The active patterns AP1 and AP2 may be electrically connected to the bit lines BL.

Each of the active patterns AP1 and AP2 of the semiconductor device according to the embodiment may include a channel portion 310 extending in the third direction (Z direction) and a contact portion 320 protruding from a lower surface of the channel portion 310 in the third direction (Z direction).

The channel portion 310 may be disposed between the bit line BL and the contact pad BC. The channel portion 310 may extend in the third direction (Z direction) between the bit line BL and the contact pad BC. The channel portion 310 may be disposed between the gate insulating pattern GOX and the back gate insulating pattern 113, which will be described later. An upper surface of the channel portion 310 may be in contact with the contact pad BC. In this case, the contact pad BC may recess at least a portion of the channel portion 310, but example embodiments are not limited thereto. The channel portion 310 may be electrically connected to the contact pad BC.

The upper surface of the channel portion 310 may be disposed at a higher level than the upper surfaces of the word lines WL1 and WL2. That is, the upper surface of the channel portion 310 may be disposed farther from the upper surface of the substrate 200 than the upper surfaces of the word lines WL1 and WL2. In addition, the lower surface of the channel portion 310 may be disposed at a lower level than the lower surfaces of the word lines WL1 and WL2. That is, the lower surface of the channel portion 310 may be disposed closer to the upper surface of the substrate 200 than the lower surfaces of the word lines WL1 and WL2.

Each of the channel portions 310 may include a first side surface and a second side surface facing each other in the second direction (Y direction). For example, the first side surface of the channel portion 310 of the first active pattern AP1 may be adjacent to the first word line WL1, and the second side surface of the channel portion 310 of the first active pattern AP1 may be adjacent to the back gate electrode BG. In addition, the first side surface of the channel portion 310 of the second active pattern AP2 may be adjacent to the back gate electrode BG, and the second side surface of the channel portion 310 of the second active pattern AP2 may be adjacent to the second word line WL2.

The channel portion 310 may have a substantially uniform width. For example, the second width W2 of the channel portion 310 along the second direction (Y direction) may be substantially uniform. That is, the distance between the first side surface and the second side surface facing each other in the second direction (Y direction) of each of the channel portions 310 may be substantially uniform. In addition, the width of the channel portion 310 of the first active pattern AP1 along the second direction (Y direction) and the width of the second active pattern AP2 along the second direction (Y direction) may be substantially the same, but example embodiments are not limited thereto.

In various example embodiments, the channel portion 310 may include a semiconductor material. The semiconductor material may include silicon. For example, the channel portion 310 may include single crystal silicon. The channel portion 310 may be doped with impurities (for example, phosphorus (P) or the like). For example, impurities of a first concentration may be doped into an area of the channel portion 310 adjacent to the contact pad BC and an area of the channel portion 310 adjacent to the bit line BL, and impurities of a second concentration less than the first concentration may be doped into a central area of the channel portion 310. However, various example embodiments are not limited thereto, and as another example, the channel portion 310 may not be doped with impurities. As another example, a partial area of the channel portion 310 may be doped with impurities, and the remaining area thereof may not be doped with impurities.

The channel portion 310 may be controlled by the first and second word lines WL1 and WL2 and the back gate electrodes BG during operation of the semiconductor device. Since the channel portion 310 is made of a single crystal semiconductor material, leakage current characteristics of the semiconductor memory device may be improved.

The contact portion 320 may extend from the lower surface of the channel portion 310 in the third direction (Z direction). The contact portion 320 may be disposed between the channel portion 310 and the first conductive pattern 165. That is, the contact portion 320 may extend from the lower surface of the channel portion 310 toward the first conductive pattern 165 in the third direction (Z direction).

The contact portion 320 may penetrate at least a portion of the bit line BL to be electrically connected to the first conductive pattern 165. For example, the contact portion 320 may penetrate the second conductive pattern 161 and the third conductive pattern 163 to be in contact with the first conductive pattern 165. Accordingly, the side surface of the contact portion 320 may be in contact with the third conductive pattern 163 and the second conductive pattern 161. In addition, the lower surface of the contact portion 320 may be in contact with the first conductive pattern 165. Here, the lower surface of the contact portion 320 may refer to one end of the contact portion 320 along the third direction (Z direction). Accordingly, the channel portion 310 and the bit lines BL may be electrically connected to each other by the contact portion 320.

The contact portion 320 may be formed by a selective epitaxial growth (SEG) using the channel portion 310 as a seed. In this case, the process temperature may be controlled to be about 430° C. or less during the selective epitaxial growth of the contact portion 320. Under these conditions, the activation concentration of impurities may increase in the process of forming the contact portion 320. A description of the activation concentration of impurities will be described later. The contact portion 320 may be integrally formed with the channel portion 310, and a boundary between the contact portion 320 and the channel portion 310 may not be visually recognized, but example embodiments are not limited thereto.

Accordingly, the first width W1 of the contact portion 320 in the second direction (Y direction) may be greater than the second width W2 of the channel portion 310 in the second direction (Y direction). Here, the first width W1 of the contact portion 320 in the second direction (Y direction) may mean the maximum width of the contact portion 320 in the second direction (Y direction). For example, the first width W1 of the contact portion 320 along the second direction (Y direction) may mean the width of the upper end portion of the contact portion 320 along the second direction (Y direction), but example embodiments are not limited thereto. In addition, the second width W2 of the channel portion 310 along the second direction (Y direction) may mean the maximum width of the channel portion 310 along the second direction (Y direction).

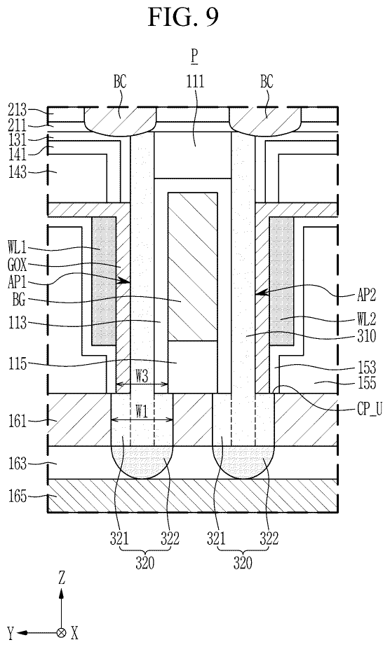

The contact portion 320 may overlap the gate insulating pattern GOX, the channel portion 310, and the back gate insulating pattern 113, which will be described later, in the third direction (Z direction). The upper surface of the contact portion 320 may be in contact with the gate insulating pattern GOX, the channel portion 310, and the back gate insulating pattern 113. For example, the contact portion 320 may completely overlap the gate insulating pattern GOX, the channel portion 310, and the back gate insulating pattern 113 in the third direction (Z direction). In various example embodiments, the first width W1 of the contact portion 320 along the second direction (Y direction) may be substantially the same as a distance between the side surface of the gate insulating pattern GOX facing the first word line WL1 and the side surface of the back gate insulating pattern 113 facing the back gate electrode BG. That is, one side surface of the contact portion 320 along the second direction (Y direction) may be aligned with one side surface of the gate insulating pattern GOX along the second direction (Y direction). The other side surface of the contact portion 320 along the second direction (Y direction) may be aligned with one side surface of the back gate insulating pattern 113 along the second direction (Y direction). However, various example embodiments are not limited thereto, and the contact portion 320 may overlap the first gate separation pattern 153 and the second gate separation pattern 155 in the third direction (Z direction). This will be described later with reference to FIG. 9.

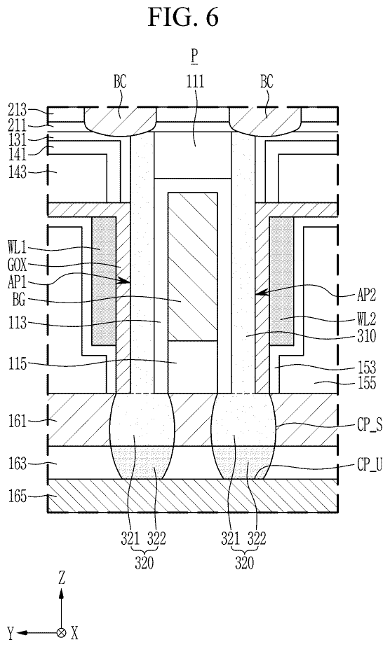

In various example embodiments, the width of the contact portion 320 along the second direction (Y direction) may include a portion that decreases as it approaches the upper surface of the substrate 200. However, various example embodiments are not limited thereto, and the contact portion 320 may further include a portion having a substantially uniform width in the second direction (Y direction). Alternatively, the width of the contact portion 320 in the second direction (Y direction) may further include a portion that increases as it approaches the upper surface of the substrate 200. This will be described later with reference to FIG. 6 to FIG. 8.

In this case, the activation concentration of the impurities doped into the contact portion 320 may be greater than the activation concentration of the impurities doped into the second conductive pattern 161. For example, the activation concentration of the impurities doped into the contact portion 320 may be greater than about 2×10²⁰ cm⁻³ and less than about 1×10²¹ cm⁻³. Meanwhile, as described above, the activation concentration of the impurities doped into the second conductive pattern 161 may be less than or equal to about 2×10²⁰ cm⁻³. Here, the activation concentration may mean the concentration of impurities that may perform a dopant function by replacing the semiconductor material element with the impurities when the contact portion 320 includes a semiconductor material with doped impurities. For example, when the contact portion 320 includes silicon (Si) doped with impurities (for example, phosphorus (P)), at least some of the impurities may be substituted with the silicon element, and the others may not be substituted with the silicon element. In this case, the activation concentration of the impurities of the contact portion 320 may mean the concentration of the impurities substituted with the silicon element. In other words, it may mean the content (at %) of impurities combined with the silicon element. Meanwhile, the activation concentration of the impurities doped into the contact portion 320 may be smaller than the total concentration of the impurities doped into the contact portion 320. The activation concentration of the doped impurities may be detected through secondary ion mass spectroscopy (SIMS), X-ray diffraction, or the like. Alternatively, the difference in the activation concentration of the impurities may be calculated by detecting the specific resistance of silicon.

The contact portion 320 of the semiconductor device according to the embodiment may include a first portion 321 and a second portion 322.

The first portion 321 may extend from the lower surface of the channel portion 310 in the third direction (Z direction). The first portion 321 may overlap the second conductive pattern 161 in a horizontal direction (for example, the first direction (X direction) and/or the second direction (Y direction)). The thickness of the first portion 321 along the third direction (Z direction) may be substantially the same as the thickness of the second conductive pattern 161 along the third direction (Z direction), but example embodiments are not limited thereto. The first portion 321 may be formed by a selective epitaxial growth (SEG) using the channel portion 310 as a seed. The first portion 321 may be integrally formed with the channel portion 310, and a boundary between the first portion 321 and the channel portion 310 may not be visually recognized, but example embodiments are not limited thereto.

In various example embodiments, the first portion 321 may include a semiconductor material doped with impurities. Here, the semiconductor material may be silicon. The first portion 321 may include the same material as the channel portion 310. For example, the first portion 321 may include single crystal silicon doped with impurities. The impurities doped into the first portion 321 may include the same material as the impurities doped into the second conductive pattern 161. For example, the impurity may include phosphorus (P), but example embodiments are not limited thereto.

In this case, the activation concentration of the impurities doped into the first portion 321 may be greater than the activation concentration of the impurities doped into the second conductive pattern 161. For example, the activation concentration of the impurities doped into the first portion 321 may be greater than about 2×10²⁰ cm⁻³ and less than about 1×10²¹ cm⁻³. In this range, the internal resistance of the contact portion 320 may be reduced due to the impurities, and the current between the bit line BL and the channel portion 310 may be improved. This may be due to process characteristics including single crystal silicon as the first portion 321 is formed from the lower surface of the channel portion 310 through the selective epitaxial growth (SEG), and amorphous silicon (a-Si) as the second conductive pattern 161 is formed on the first gate separation pattern 153 and the second gate separation pattern 155.

In various example embodiments, the activation concentration of the impurities doped into the first portion 321 may be greater than the activation concentration of the impurities doped into the third conductive pattern 163. This is because, as the first portion 321 includes single crystal silicon, the degree to which the doped impurities are activated may be relatively greater than that of the third conductive pattern 163 including amorphous silicon (a-Si).

In addition, the activation concentration of the impurities doped into the first portion 321 may be greater than the activation concentration of the impurities doped into the channel portion 310, but example embodiments are not limited thereto, and the activation concentration of the impurities doped into the first portion 321 may be less than or equal to the activation concentration of the impurities doped into the channel portion 310.

The second portion 322 may be disposed on the lower surface of the first portion 321. The second portion 322 may be disposed between the first portion 321 and the first conductive pattern 165. The second portion 322 may extend from the lower surface of the first portion 321 in the third direction (Z direction). The second portion 322 may overlap the third conductive pattern 163 in a horizontal direction (for example, the first direction (X direction) and/or the second direction (Y direction)). The thickness of the second portion 322 along the third direction (Z direction) may be substantially the same as the thickness of the third conductive pattern 163 along the third direction (Z direction), but example embodiments are not limited thereto. In various example embodiments, the second portion 322 may be in contact with the first conductive pattern 165.

The second portion 322 may have a curved shape in a cross sectional view, but example embodiments are not limited thereto. For example, the second portion 322 may have a polygonal shape in a cross section view. This will be described later with reference to FIG. 6 to FIG. 8.

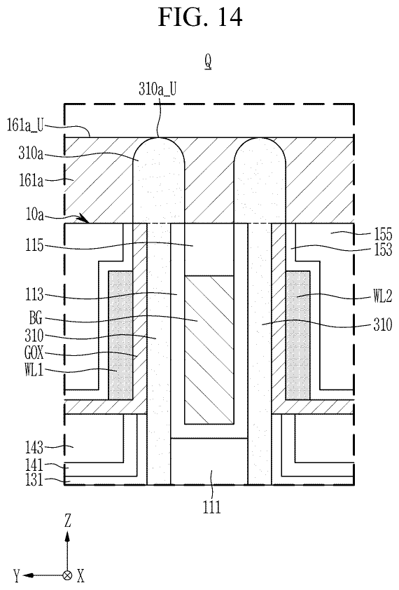

In various example embodiments, the second portion 322 may be formed by silicidizing at least a portion of a pre-contact portion (310a of FIG. 14) through a heat treatment process after forming the pre-contact portion (310a of FIG. 14) through a selective epitaxial growth (SEG) using the channel portion 310 as a seed.

The second portion 322 may include the same material as the third conductive pattern 163. The second portion 322 may include a metal silicide material. For example, the second portion 322 may include titanium silicide, cobalt silicide, nickel silicide, or a combination thereof, but example embodiments are not limited thereto. The second portion 322 may be doped with impurities.

In this case, the activation concentration of the impurities doped into the second portion 322 may be less than that of the impurities doped into the first portion 321. This may be due to the process characteristics of forming the pre-contact portion (310a of FIG. 14) and silicidizing at least a portion of the pre-contact portion (310a of FIG. 14) through heat treatment to form the second portion 322. In addition, the activation concentration of the impurities doped into the second portion 322 may be smaller that than of the impurities doped into the third conductive pattern 163. This is because, as the second portion 322 includes single crystal silicon, the degree to which the doped impurities are activated may be relatively greater than that of the third conductive pattern 163 including amorphous silicon (a-Si).

The active patterns AP1 and AP2 of the semiconductor device according to various example embodiments may include the contact portion 320 that penetrates at least a portion of the bit line BL to electrically connect the channel portion 310 and the first conductive pattern 165. Specifically, the contact portion 320 may penetrate the second conductive pattern 161 and the third conductive pattern 163 of the bit line BL to be electrically connected to the first conductive pattern 165. Meanwhile, impurities may be activated at a relatively high concentration in the contact portion 320. Accordingly, the internal resistance of the contact portion 320 and the contact resistance between the first conductive pattern 165 and the contact portion 320 may be reduced, and electrical signals applied to the first conductive pattern 165 may be effectively transmitted to the channel portion 310 through the contact portion 320. That is, the performance of the semiconductor device may be improved.

The back gate electrodes BG may be disposed between the first active pattern AP1 and the second active pattern AP2 adjacent to each other in the second direction (Y direction). That is, the first active pattern AP1 may be disposed on one side of each back gate electrode BG, and the second active pattern AP2 may be disposed on the other side of each back gate electrode BG. The height of the back gate electrode BG in the third direction (Z direction) may be smaller than the height of the first and second active patterns AP1 and AP2 in the third direction (Z direction).

The back gate electrode BG may include a conductive material. For example, the back gate electrode BG may include at least one of doped polysilicon, conductive metal nitride, conductive metal silicon nitride, metal carbon nitride, conductive metal silicide, conductive metal oxide, two-dimensional material, and metal. However, example embodiments are not limited thereto.

The back gate electrodes BG may be applied with a negative voltage during operation of the semiconductor device, and may increase a threshold voltage of the vertical channel transistor. In other words, as the vertical channel transistor is miniaturized, the threshold voltage decreases, thereby limiting or preventing the leakage current characteristics from deteriorating.

Specifically, referring to FIG. 4, the back gate electrode BG may include a first surface adjacent to the bit line BL and a second surface adjacent to the contact pad BC. The first and second surfaces of the back gate electrode BG may be disposed at different levels from the first and second surfaces of the first and second active patterns AP1 and AP2. For example, the first surface of the back gate electrode BG may be disposed at a higher level than the first surface of the first and second active patterns AP1 and AP2. That is, the first surface of the back gate electrode BG may be disposed farther from the upper surface of the substrate 200 than the first surfaces of the first and second active patterns AP1 and AP2. In addition, the second surface of the back gate electrode BG may be disposed at a lower level than the second surface of the first and second active patterns AP1 and AP2. That is, the second surface of the back gate electrode BG may be disposed closer to the upper surface of the substrate 200 than the second surfaces of the first and second active patterns AP1 and AP2. Here, the first surface of the back gate electrode BG may mean the lower surface of the back gate electrode BG, and the second surface of the back gate electrode BG may mean the upper surface of the back gate electrode BG.

The semiconductor device according to the embodiment may further include a back gate separation pattern 111, a back gate insulating pattern 113, and a back gate capping pattern 115.

The back gate separation pattern 111 may be disposed on the back gate electrode BG. The back gate separation pattern 111 may be disposed between the first and second active patterns AP1 and AP2 adjacent to each other in the second direction (Y direction). The back gate separation pattern 111 may extend parallel to the back gate electrodes BG in the first direction (X direction). The back gate separation pattern 111 may include an insulating material. For example, the back gate separation pattern 111 may include one of a silicon oxide, a silicon oxynitride, a silicon nitride, and a combination thereof. However, example embodiments are not limited thereto.

The back gate insulating pattern 113 may be disposed between the back gate electrode BG and the first active pattern AP1 and between the back gate electrode BG and the second active pattern AP2. The back gate insulating pattern 113 may be disposed between the back gate separation pattern 111 and the back gate electrode BG. The back gate insulating pattern 113 may include vertical portions covering both side surfaces of the back gate electrode BG and a horizontal portion connecting the vertical portions. The horizontal portion of the back gate insulating pattern 113 is closer to the contact pad BC than the bit line BL, and may cover the second surface of the back gate electrode BG. The back gate insulating pattern 113 may include an insulating material. For example, it may include any one of a silicon oxide, a silicon oxynitride, a high dielectric constant material having a higher dielectric constant than a silicon oxide, or a combination thereof. However, example embodiments are not limited thereto.

The back gate capping pattern 115 may be disposed between the bit line BL and the back gate electrode BG. The back gate capping pattern 115 may be disposed between the first active pattern AP1 and the second active pattern AP2 adjacent in the second direction (Y direction). The back gate capping pattern 115 may extend parallel to the bit line BL and the back gate electrode BG in the first direction (X direction).

The lower surface of the back gate capping pattern 115 may be in direct contact with the second conductive pattern 161 of the bit lines BL. The back gate capping pattern 115 may be disposed between the vertical portions of the back gate insulating pattern 113. In addition, in a cross-sectional view consisting of the first direction (X direction) and the third direction (Z direction), the back gate capping pattern 115 may be disposed on the bit lines BL between the spacer insulating layers 171. The back gate capping pattern 115 may include an insulating material. For example, it may include one of a silicon oxide, a silicon oxynitride, a silicon nitride, and a combination thereof. However, example embodiments are not limited thereto.

The word lines WL1 and WL2 may include a first word line WL1 and a second word line WL2. The first word line WL1 and the second word line WL2 may be disposed on the bit line BL.

Each of the first word line WL1 and the second word line WL2 may extend in the first direction (X direction). The first word line WL1 and the second word line WL2 may be alternately arranged in the second direction (Y direction).

The first word line WL1 may be disposed on one side of the first active pattern AP1, and the second word line WL2 may be disposed on the other side of the second active pattern AP2. The first active patterns AP1 and the second active patterns AP2 may be disposed between the first word line WL1 and the second word line WL2 adjacent to each other in the second direction (Y direction).

Each of the first word line WL1 and the second word line WL2 may extend in the third direction (Z direction). The first word line WL1 and the second word line WL2 may be spaced apart from the bit line BL and the contact pad BC in the third direction (Z direction). The first word line WL1 and the second word line WL2 may be disposed between the bit line BL and the contact pad BC. In some example embodiments, each of the first word line WL1 and the second word line WL2 may further include a portion extending in the second direction (Y direction). That is, each of the first word line WL1 and the second word line WL2 may have an L-shape in a cross-sectional view formed in the second direction (Y direction) and the third direction (Z direction).

In various example embodiments, an extension length of the first and second word lines WL1 and WL2 along the third direction (Z direction) may be smaller than an extension length of the first and second active patterns AP1 and AP2 along the third direction (Z direction). A height of the first and second word lines WL1 and WL2 along the third direction (Z direction) may be substantially equal to or smaller than a height of the back gate electrodes BG along the third direction (Z direction). Specifically, the upper surfaces of the first and second word lines WL1 and WL2 may be disposed at a lower level than the upper surfaces of the first and second active patterns AP1 and AP2. The upper surfaces of the first and second word lines WL1 and WL2 may be disposed closer to the upper surface of the substrate 200 than the upper surfaces of the first and second active patterns AP1 and AP2. In addition, the lower surfaces of the first and second word lines WL1 and WL2 may be disposed at a higher level than the lower surfaces of the first and second active patterns AP1 and AP2. The lower surfaces of the first and second word lines WL1 and WL2 may be disposed farther from the upper surface of the substrate 200 than the lower surfaces of the first and second active patterns AP1 and AP2.

The first and second words lines WL1 and WL2 may include a conductive material. For example, it may include one of a doped polysilicon, a conductive metal nitride, a conductive metal silicon nitride, a metal carbon nitride, a conductive metal silicide, a conductive metal oxide, a two-dimensional material, a metal, or a combination thereof. However, example embodiments are not limited thereto.

The semiconductor device according to the embodiment may further include a gate insulating pattern GOX, a gate capping pattern 143, first and second etching stop films 131 and 141, a first gate separation pattern 153, a second gate separation pattern 155, third and fourth etching stop films 211 and 213, and an interlayer insulating layer 231.

The gate insulating pattern GOX may be disposed between the first word line WL1 and the first active pattern AP1 and the second word line WL2 and the second active patterns AP2. The gate insulating patterns GOX may extend parallel to the first and second word lines WL1 and WL2 in the first direction (X direction). The gate insulating pattern GOX may extend along one side surface of the first active pattern AP1 and may extend along one side surface of the second active pattern AP2. The gate insulating pattern GOX may surround at least some of the first word line WL1 and the second word line WL2. The gate insulating pattern GOX has a substantially uniform thickness and may be conformally extended.

The gate insulating pattern GOX may include a vertical portion adjacent to the first and second active patterns AP1 and AP2 and a horizontal portion extending from the vertical portion in the second direction (Y direction). The gate insulating pattern GOX between the first active pattern AP1 and the first word line WL1 may be separated from the gate insulating pattern GOX between the second active pattern AP2 and the second word line WL2.

The gate insulating pattern GOX may include an insulating material. For example, the gate insulating pattern GOX may include one of a silicon oxide film, a silicon oxynitride film, a high dielectric film having a higher dielectric constant than the silicon oxide film, and a combination thereof. Here, the high dielectric film may include a metal oxide or a metal oxynitride. For example, a high dielectric film usable as the gate insulating pattern GOX may include one of HfO₂, HfSiO, HfSiON, HfTaO, HfTiO, HfZrO, ZrO₂, Al₂O₃, and a combination thereof, but example embodiments are not limited thereto.

The gate capping pattern 143 may be disposed on the gate insulating pattern GOX. For example, the gate capping pattern 143 may be disposed between the horizontal portion of the gate insulating pattern GOX and the contact pad BC.

The first and second etching stop films 131 and 141 may be disposed on the gate capping pattern 143. The first and second etching stop films 131 and 141 may be disposed between the first and second active patterns AP1 and AP2 and the gate capping pattern 143.

The gate capping pattern 143 and the first and second etching stop films 131 and 141 may include an insulating material. For example, the gate capping pattern 143 and the first and second etching stop films 131 and 141 may include one of a silicon oxide, a silicon oxynitride, a silicon nitride, and a combination thereof. However, example embodiments are not limited thereto.

The first gate separation pattern 153 and the second gate separation pattern 155 may be disposed on the bit line BL. The first gate separation pattern 153 and the second gate separation pattern 155 may extend in the first direction (X direction) between the first word line WL1 and the second word line WL2. The second gate separation pattern 155 may be disposed between the bit line BL and the first word line WL1, between the bit line BL and the gate insulating pattern GOX, and between the bit line BL and the second word line WL2. The first gate separation pattern 153 may be disposed on the first gate separation pattern 153. The first gate separation pattern 153 may be disposed between the first gate separation pattern 153 and the first word line WL1, between the first gate separation pattern 153 and the second word line WL2, and between the second gate separation pattern 155 and the gate insulating pattern GOX.

The first gate separation pattern 153 may be in direct contact with the first and second word lines WL1 and WL2. The first gate separation pattern 153 may have a substantially uniform thickness, and may conformally extend along the side surfaces of the gate insulating pattern GOX and the first and second word lines WL1 and WL2. The first gate separation pattern 153 and the second gate separation pattern 155 may be in contact with the upper surface of the second conductive pattern 161, but example embodiments are not limited thereto.

In various example embodiments, the first gate separation pattern 153 and the second gate separation pattern 155 may not be in contact with the contact portion 320, but example embodiments are not limited thereto. For example, the lower surface of at least one of the first gate separation pattern 153 and the second gate separation pattern 155 may be in contact with the contact portion 320. This will be described later with reference to FIG. 9.

Each of the first gate separation pattern 153 and the second gate separation pattern 155 may include an insulating material. For example, the first gate separation pattern 153 and the second gate separation pattern 155 may include one of a silicon oxide, a silicon oxynitride, a silicon nitride, and a combination thereof. However, example embodiments are not limited thereto.

The third and fourth etching stop films 211 and 213 and the interlayer insulating layer 231 may cover the upper surfaces of the first and second active patterns AP1 and AP2. The third and fourth etching stop films 211 and 213 and the interlayer insulating layer 231 may include an insulating material. For example, the third and fourth etching stop films 211 and 213 and the interlayer insulating layer 231 may include one of a silicon oxide, a silicon oxynitride, a silicon nitride, and a combination thereof. However, example embodiments are not limited thereto.

The semiconductor device according to the embodiment may further include contact pads BC, landing pads LP, a pad separation insulating pattern 245, a fifth etching stop film 247, and an upper insulating layer 270.

The contact pads BC may penetrate the third and fourth etching stop films 211 and 213 and the interlayer insulating layer 231. The contact pads BC may be connected to the first and second active patterns AP1 and AP2, respectively. The contact pads BC may be in contact with the upper surfaces of the first and second active patterns AP1 and AP2. The contact pads BC may have a lower width greater than an upper width in a cross-sectional view formed in the second direction (Y direction) and the third direction (Z direction). The contact pads BC adjacent to each other may be separated from each other by the pad separation insulating patterns 245.

Each of the contact pads BC may have various shapes, such as circular, elliptical, rectangular, square, rhombic, and hexagonal shapes in a plan view. The contact pads BC may include a conductive material. For example, the contact pads BC may include at least one of doped polysilicon, conductive metal nitride, conductive metal silicon nitride, metal carbon nitride, conductive metal silicide, conductive metal oxide, two-dimensional material, and metal. However, example embodiments are not limited thereto.

The landing pads LP may be disposed on the contact pad BC. The landing pads LP may have various shapes, such as circular, elliptical, rectangular, square, rhombic, and hexagonal shapes in a plan view. The landing pad LP may include a conductive material. For example, the landing pad LP may include at least one of doped polysilicon, conductive metal nitride, conductive metal silicon nitride, metal carbon nitride, conductive metal silicide, conductive metal oxide, two-dimensional material, and metal. However, example embodiments are not limited thereto.

The pad separation insulating patterns 245 may be disposed between the landing pads LP. The landing pads LP may be arranged in a matrix pattern along the first direction (X direction) and the second direction (Y direction) in a plan view. The upper surface of the landing pad LP may be substantially coplanar with the upper surface of the pad separation insulating pattern 245.

The fifth etching stop film 247 may be disposed on the pad separation insulating pattern 245. The fifth etching stop film 247 may include an insulating material. For example, the fifth etching stop film 247 may include one of a silicon oxide, a silicon oxynitride, a silicon nitride, and a combination thereof.

The data storage patterns DSP may be disposed on the landing pads LP, respectively. The data storage patterns DSP may be electrically connected to the first and second active patterns AP1 and AP2, respectively.

As shown in FIG. 1, the data storage patterns DSP may be arranged in a matrix format along the first direction (X direction) and the second direction (Y direction). The data storage patterns DSP may completely overlap or partially overlap the landing pads LP in the third direction (Z direction). The data storage patterns DSP may be in contact with all or some of the upper surfaces of the landing pads LP.

In various example embodiments, the data storage patterns DSP may be capacitors. The data storage patterns DSP may include a capacitor dielectric film 253 interposed between the storage electrodes 251 and the plate electrode 255. In this case, the storage electrode 251 may contact the landing pad LP. The storage electrodes 251 may penetrate the fifth etching stop film 247. The storage electrode 251 may have various shapes, such as circular, elliptical, rectangular, square, rhombic, and hexagonal shapes in a plan view.

In some example embodiments, the data storage patterns DSP may be variable resistance patterns that may be switched into two resistance states by an electrical pulse applied to a memory element. For example, the data storage patterns DSP may include phase-change materials whose crystal states change depending on an amount of current, perovskite compounds, transition metal oxides, magnetic materials, ferromagnetic materials, or antiferromagnetic materials.

Although not shown, a memory cell contact plug (not shown) connected to the plate electrode 255 may be disposed on the data storage patterns DSP.

The upper insulating layer 270 may be disposed on the data storage patterns DSP. The upper insulating layer 270 may cover the plate electrode 255. The upper insulating layer 270 may include an insulating material. For example, the upper insulating layer 270 may include at least one of a silicon oxide, a silicon oxynitride, a silicon nitride, and a combination thereof. However, example embodiments are not limited thereto.

Although not shown, the peripheral connection area of the semiconductor device according to the embodiment may further include a peripheral active pattern, an element separation layer surrounding the peripheral active pattern, a peripheral gate electrode functioning as a gate electrode of a peripheral circuit transistor, a peripheral gate insulating layer surrounding at least a portion of the peripheral gate electrode, and a plurality of bit line contact plugs electrically connected to the bit line BL. In this case, the peripheral circuit transistor may configure row and column decoders, a sense amplifier, or control logics. However, this is an example, and the type and role of the peripheral circuit transistor are not limited thereto, and may be variously changed depending on the design of the semiconductor device.

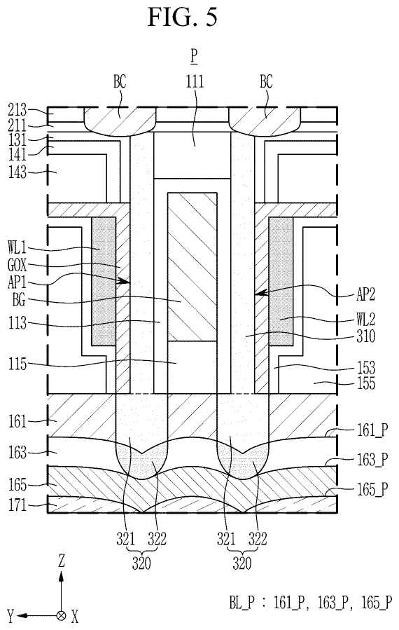

Hereinafter, a semiconductor device according to some example embodiments will be described with reference to FIG. 5 to FIG. 9.

FIG. 5 to FIG. 9 illustrate partial enlarged views corresponding to area “P” of FIG. 4 illustrating a semiconductor device according to some example embodiments.

The embodiment illustrated in FIG. 5 to FIG. 9 has considerably the same portions as the embodiment illustrated in FIG. 1 to FIG. 4, so a description thereof will be omitted and differences will be mainly described.

Referring to FIG. 5, the bit lines BL of the semiconductor device according to some example embodiments may further include a protruding portion BL_P.

The protruding portion BL_P of the bit line BL may be disposed between the contact portions 320. The protruding portion BL_P of the bit line BL may protrude in a direction away from the upper surface of the substrate 200. That is, the protruding portion BL_P of the bit line BL may have a convex shape in a direction away from the upper surface of the substrate 200 in a cross-sectional view. The protruding portion BL_P of the bit line BL may be repeatedly disposed along the second direction (Y direction). For example, the protruding portion BL_P of the bit line BL may be disposed on one side and the other side of the contact portion 320 in the second direction (Y direction). Accordingly, the bit line BL may have a wave shape, but example embodiments are not limited thereto.

Specifically, each of the first conductive pattern 165 to the third conductive pattern 163 may include a protruding portion. That is, each of the protruding portion 165_P of the first conductive pattern 165, the protruding portion 161_P of the second conductive pattern 161, and the protruding portion 163_P of the third conductive pattern 163 may protrude in a direction away from the upper surface of the substrate 200 between the contact portions 320. Each of the upper surface of the first conductive pattern 165, the upper surface of the second conductive pattern 161, and the upper surface of the third conductive pattern 163 may have a convex shape in a direction away from the upper surface of the substrate 200. In addition, each of the lower surface of the first conductive pattern 165, the lower surface of the second conductive pattern 161, and the lower surface of the third conductive pattern 163 may include a convex shape in a direction away from the upper surface of the substrate 200. Each of the protruding portion 165_P of the first conductive pattern 165, the protruding portion 161_P of the second conductive pattern 161, and the protruding portion 163_P of the third conductive pattern 163 may be repeatedly disposed in the second direction (Y direction). Accordingly, each of the upper surface of the first conductive pattern 165, the upper surface of the second conductive pattern 161, and the upper surface of the third conductive pattern 163 may have a wave shape, but example embodiments are not limited thereto.

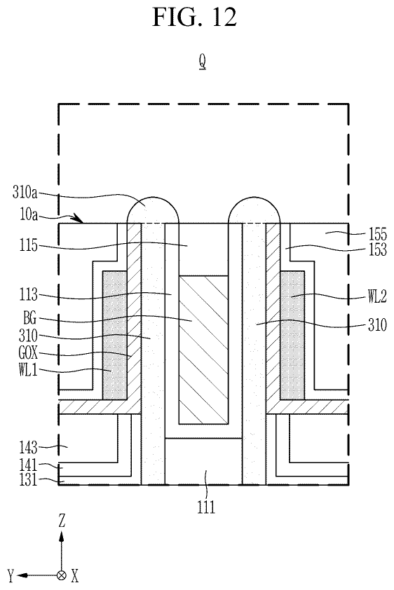

The shape of the protruding portion BL_P of the bit line BL according to some example embodiments may be due to the characteristics of the process for removing at least a portion of a pre-conductive pattern (161a in FIG. 14) together and forming the bit line BL by conformally depositing a conductive material on the pre-conductive pattern (161a in FIG. 14) and a pre-contact portion (310a in FIG. 14), in a process of forming a pre-contact portion (310a in FIG. 14) and a pre-conductive pattern (161a in FIG. 14) to a sufficient thickness when forming the pre-contact portion (310a in FIG. 14) and the pre-conductive pattern (161a of FIG. 14) and flattening the pre-contact portion (310a in FIG. 14) and the pre-conductive pattern (161a of FIG. 14) using a chemical mechanical polishing process. This will be described in detail later with reference to FIG. 12.

However, various example embodiments are not limited thereto, and the shape of the protruding portion BL_P of the bit line BL may be due to the characteristics of the process for forming the bit line BL by forming the pre-contact portion (310a in FIG. 14) and the pre-conductive pattern (161a in FIG. 14) and conformally forming the third conductive pattern (163a in FIG. 14) and the first conductive pattern 165 on one surfaces of the pre-contact portion (310a in FIG. 14) and the pre-conductive pattern (161a in FIG. 14), in the process of forming the pre-contact portion (310a in FIG. 14) and the pre-conductive pattern (161a in FIG. 14) using a selective epitaxial growth (SEG). In this case, one surface of the pre-conductive pattern (161a in FIG. 14) may have a concave shape due to a difference in growth speed between the pre-contact portion (310a in FIG. 14) and the pre-conductive pattern (161a in FIG. 14), and accordingly, the protruding portion 165_P of the first conductive pattern 165 to the protruding portion 163_P of the third conductive pattern 163 may have a convex shape in a direction away from the upper surface of the substrate 200.

Accordingly, an interface between the first portion 321 and the second portion 322 of the active patterns AP1 and AP2 of the semiconductor device according to some example embodiments may include a curved surface, but example embodiments are not limited thereto.

In FIG. 5, the upper and lower surfaces of each of the first conductive pattern 165 to the third conductive pattern 163 are shown as including a convex shape, but example embodiments are not limited thereto. For example, the upper surface of the first conductive pattern 165 may have a convex shape, and the lower surface of the first conductive pattern 165 may be flat. As another example, the upper and lower surfaces of the first conductive pattern 165 may be flat.

Referring to FIG. 6, the side surface CP_S of the contact portion 320 of the semiconductor device according to some example embodiments may have a convex shape. For example, the side surface CP_S of the contact portion 320 may include a curved surface. Accordingly, the width of the contact portion 320 in the second direction (Y direction) may increase and then decrease as the distance from the lower surface of the channel portion 310 increases.

In some example embodiments, the lower surface CP_U of the contact portion 320 may be in contact with the first conductive pattern 165. For example, the lower surface CP_U of the contact portion 320 may be flat, and the lower surface CP_U of the contact portion 320 may be in contact with the first conductive pattern 165. This may be due to the characteristics of the process of flattening the pre-contact portion (310a in FIG. 14) using a chemical mechanical polishing process after forming the pre-contact portion (310a in FIG. 14) to a sufficient thickness, and forming the first conductive pattern 165 and the second conductive pattern 161 on the pre-contact portion (310a in FIG. 14), in the process of forming the contact portion 320. The lower surface CP_U of the contact portion 320 may be disposed on the same plane as the lower surface of the second conductive pattern 161, but example embodiments are not limited thereto.

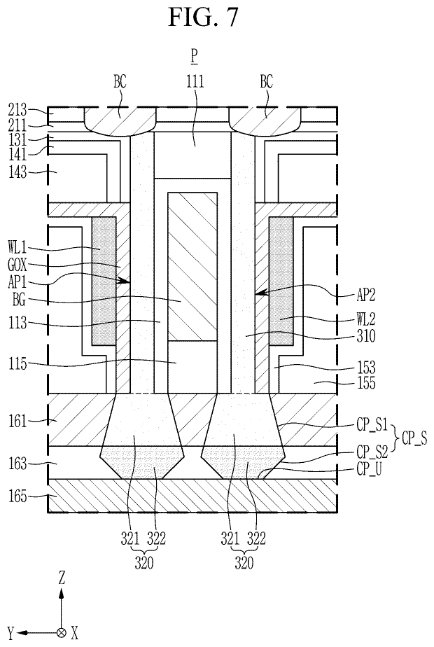

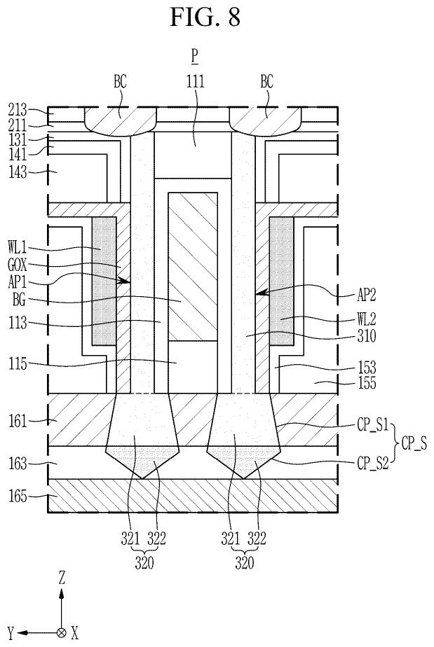

Referring to FIG. 7 and FIG. 8, the side surface CP_S of the contact portion 320 of the semiconductor device according to some example embodiments may include a plurality of inclined surfaces CP_S1 and CP_S2 inclined from the upper surface of the substrate 200. For example, the first inclined surface CP_S1 of the contact portion 320 may be inclined at a desired (and/or alternatively predetermined) angle from the lower surface of the channel portion 310. The first inclined surface CP_S1 of the contact portion 320 may extend in one direction. For example, the first inclined surface CP_S1 of the contact portion 320 may extend straightly in a direction inclined at a desired (and/or alternatively predetermined) angle from the lower surface of the channel portion 310. Accordingly, the width of the first portion 321 of the contact portion 320 in the second direction (Y direction) may increase as the distance from the lower surface of the channel portion 310 increases, but example embodiments are not limited thereto. The second inclined surface CP_S2 of the contact portion 320 may be inclined at a desired (and/or alternatively predetermined) angle from the upper surface of the first conductive pattern 165. The second inclined surface CP_S2 of the contact portion 320 may extend in one direction. For example, the second inclined surface CP_S2 of the contact portion 320 may extend straightly in a direction inclined at a desired (and/or alternatively predetermined) angle from the upper surface of the first conductive pattern 165. The second inclined surface CP_S2 of the contact portion 320 may be configured of at least a portion of a side surface of the second portion 322. In this case, the width of the second portion 322 of the contact portion 320 in the second direction (Y direction) may decrease as the distance from the lower surface of the channel portion 310 increases.

Accordingly, the contact portion 320 may have a polygonal shape in a cross-sectional view formed in the second direction (Y direction) and the third direction (Z direction). For example, as shown in FIG. 7, the contact portion 320 may have a hexagonal shape in a cross-sectional view formed in the second direction (Y direction) and the third direction (Z direction). Alternatively, as shown in FIG. 8, the contact portion 320 may have a pentagonal shape in a cross-sectional view formed in the second direction (Y direction) and the third direction (Z direction). This may be due to the difference in growth rate in the crystal plane direction of the material (for example, silicon (Si)) configuring the contact portion 320, in the process of forming the contact portion 320 through the selective epitaxial growth (SEG) using the channel portion 310 as a seed. However, various example embodiments are not limited thereto, and the cross-sectional shape of the contact portion 320 may be variously changed.

Referring to FIG. 9, the contact portion 320 of the semiconductor device according to some example embodiments may be in contact with at least one of the first gate separation pattern 153 and the second gate separation pattern 155.

In various example embodiments of FIG. 1 to FIG. 4, one side surface of the contact portion 320 may be aligned with the side surface of the gate insulating pattern GOX in the third direction (Z direction). In addition, the other side surface of the contact portion 320 may be aligned with the side surface of the back gate insulating pattern 113 in the third direction (Z direction). In various example embodiments of FIG. 9, the contact portion 320 may further protrude in the second direction (Y direction).

In some example embodiments, the first width W1 of the contact portion 320 along the second direction (Y direction) may be greater than the third distance W3 between the side surface of the gate insulating pattern GOX facing the first word line WL1 and the side surface of the back gate insulating pattern 113 facing the back gate electrode BG. Here, the first width W1 of the contact portion 320 in the second direction (Y direction) may mean the maximum width of the contact portion 320 in the second direction (Y direction). The contact portion 320 may overlap at least one of the first gate separation pattern 153 and the second gate separation pattern 155 in the third direction (Z direction). In addition, the contact portion 320 may overlap the back gate capping pattern 115 in the third direction (Z direction). The upper surface CP_U of the contact portion 320 may be in contact with at least one of the first gate separation pattern 153, the second gate separation pattern 155, and the back gate capping pattern 115.

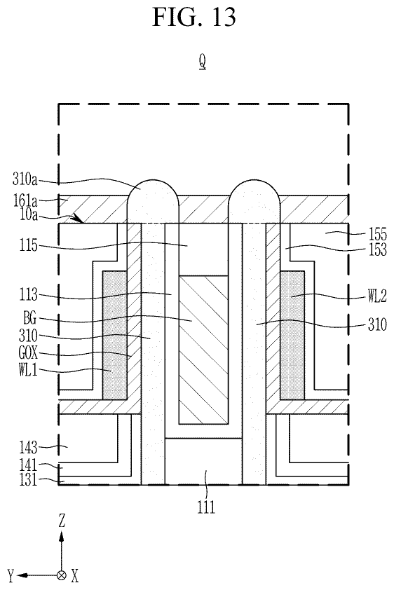

Hereinafter, a manufacturing method of a semiconductor device according to various example embodiments will be described with reference to FIG. 1 and FIG. 10 to FIG. 23.

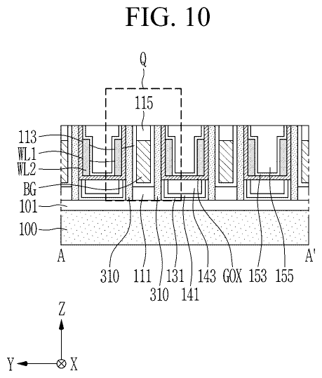

FIG. 10 illustrates a cross-sectional view taken along line A-A′ of FIG. 1, illustrating a method of manufacturing a semiconductor device according to various example embodiments.

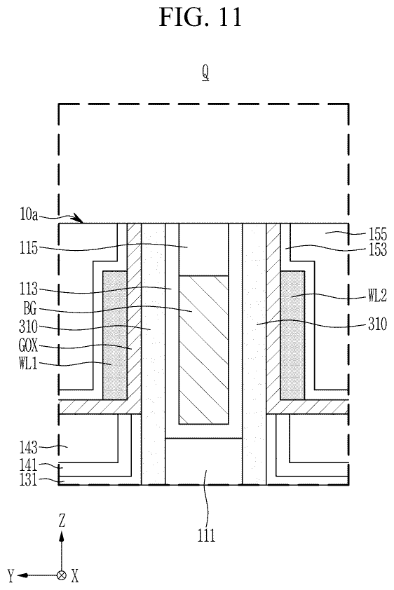

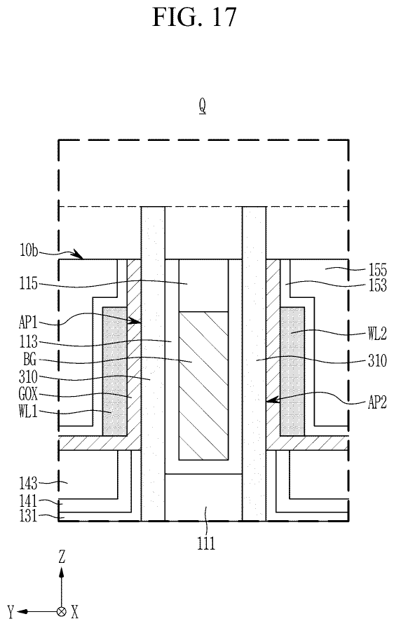

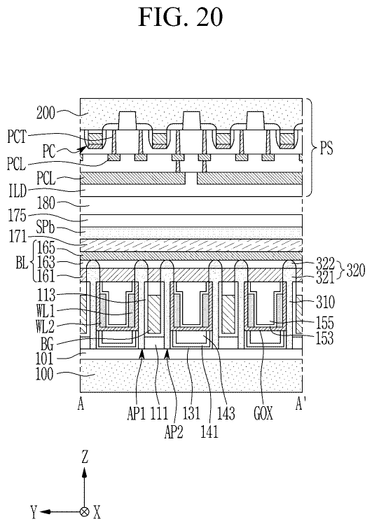

FIG. 11 to FIG. 16 illustrate partial enlarged views corresponding to area “Q” of FIG. 10, illustrating a method of manufacturing a semiconductor device according to various example embodiments. FIG. 17 to FIG. 19 illustrate partial enlarged views corresponding to area “Q” of FIG. 10, illustrating a method of manufacturing a semiconductor device according to some example embodiments. FIG. 20 to FIG. 23 illustrates cross-sectional views taken along line A-A′ of FIG. 1, illustrating a method of manufacturing a semiconductor device according to various example embodiments.

First, referring to FIG. 10 and FIG. 11 together with FIG. 1, a substrate 200 structure including a sub-substrate 100, a buried insulating layer 101, and active layer (not shown) may be prepared. The sub-substrate 100 may be, for example, a silicon substrate 200, a germanium substrate 200, and/or a silicon-germanium substrate 200. However, example embodiments are not limited thereto.

The buried insulating layer 101 may be a buried oxide (BOX) formed by a separation by implanted oxygen (SIMOX) method or a bonding and layer transfer method. However, various example embodiments are not limited thereto, and the buried insulating layer 101 may be an insulating film formed by a chemical vapor deposition method. The buried insulating layer 101 may include, for example, a silicon oxide film, a silicon nitride film, a silicon oxynitride film, and/or a low dielectric film. However, example embodiments are not limited thereto.

The active layer may be a single crystal semiconductor film. The active layer may be, for example, a single crystal silicon substrate 200, a germanium substrate 200, and/or a silicon-germanium substrate 200. The active layer may have a first surface and a second surface facing each other, the first surface may be in contact with the sub-substrate 100, and the second surface may be in contact with the buried insulating layer 101.

Subsequently, the active layer (not shown) may be etched using a mask pattern as an etching mask. For example, the active layer may be anisotropically etched. Accordingly, trenches may be formed in the active layer. Subsequently, after the gate separation patterns 111 filling the lower portions of the trenches are formed, the back gate insulating patterns 113 and the back gate electrodes BG may be formed in the trenches.

Next, the back gate capping patterns 115 may be formed in the trenches in which the back gate electrodes BG are formed. In this case, before forming the back gate capping patterns 115, impurities may be doped into the active layers through a trench by performing a gas phase doping (GPD) process or a plasma doping (PLAD) process. However, example embodiments are not limited thereto.

Next, a spacer film (not shown) may be formed to cover the side surfaces of the back gate insulating patterns 113 and the upper surfaces of the back gate capping patterns 115 with a substantially uniform thickness. Depending on the deposition thickness of the spacer film, the width of the active patterns of vertical channel transistors may be determined. The spacer film may include an insulating material. The spacer film may include, for example, a silicon oxide, a silicon oxynitride, a silicon nitride, a silicon carbide (SiC), a silicon carbon nitride film (SiCN), and a combinations thereof. However, example embodiments are not limited thereto.

By performing an etching process on the spacer film, a pair of spacers (not shown) may be formed on the sides of each back gate insulating pattern 113. Next, an etching process on the active layer (not shown) may be performed using the spacers as an etching mask. For example, the active layer may be anisotropically etched. Accordingly, a pair of preliminary active patterns (not shown) separated from each other may be formed on both sides of each back gate insulating pattern 113. As the preliminary active patterns are formed, the buried insulating layer 101 may be exposed.

The preliminary active patterns may extend parallel to the back gate electrode BG in the first direction X, and a trench may be formed between the preliminary active patterns adjacent to each other in the second direction Y.

Next, after the first etching stop film 131 conformally covering the inner surface of the trench, a first sacrificial film (not shown) filling the trench on which the first etching stop film 131 is formed may be formed. The first etching stop film 131 may be formed by depositing an insulating material, for example, a silicon oxide. The first sacrificial film may include an insulating material having an etching selectivity with respect to the first etching stop film 131. For example, the first sacrificial film may be one of insulating materials and a silicon oxide film formed using a spin-on glass (SOG) technology.

After a mask pattern is formed on the first sacrificial film, the first sacrificial film and the first etching stop film 131 are sequentially etched using the mask pattern as an etching mask, thereby forming openings exposing portions of the preliminary active patterns and a portion of the upper surface of the buried insulating layer 101. During the etching process for the first sacrificial film and the first etching stop film 131, the spacers may be removed together.

Next, the channel portions 310 of the active patterns AP1 and AP2 may be formed on both sides of the back gate insulating pattern 113 by anisotropically etching the preliminary active patterns. That is, the channel portions 310 of the active patterns AP1 and AP2 may be formed on one side and the other side of the back gate electrode BG.

Next, after forming the channel portion 310 of the active patterns AP1 and AP2, a second sacrificial film (not shown) may be formed in the openings. The second sacrificial film may be made of an insulating material that has an etching selectivity with respect to the first etching stop film 131.

Subsequently, the first and second sacrificial films may be removed, and the first etching stop film 131 may be exposed between the channel portions 310 of the active patterns AP1 and AP2.

Subsequently, the second etching stop film 141 may be formed to a substantially uniform thickness within the trench in which the first etching stop film 131 is formed. The second etching stop film 141 may be formed on some of the first etching stop film 131, the back gate insulating patterns 113, the back gate capping patterns 115, and the buried insulating layer 101. The second etching stop film 141 may include a material having an etching selectivity with respect to the first etching stop film 131.

Next, a gate capping pattern 143 may be formed to fill the trench in which the second etching stop film 141 is formed. The gate capping pattern 143 may be formed by forming an insulating film using SOG technology and then performing isotropic etching on the insulating film. The gate capping pattern 143 may include a fluoride silicate glass (FSG), a spin-on glass (SOG), and a Tonen SilaZene (TOSZ). However, example embodiments are not limited thereto.

The level of the upper surface of the gate capping pattern 143 may vary depending on an isotropic etching process. For example, the upper surface of the gate capping pattern 143 may be disposed at a higher level than the lower surface of the back gate electrode BG. In this case, at least portions of the first and second etching stop films 131 and 141 may be exposed.

Subsequently, at least a portion of the channel portion 310 of the active patterns AP1 and AP2 may be exposed by isotropically etching the exposed first and second etching stop films 131 and 141.

Subsequently, a gate insulating pattern GOX may be formed to conformally cover the side surfaces of the channel portion 310 of the active patterns AP1 and AP2, the upper surfaces of the back gate capping patterns 115, and the upper surface of the gate capping pattern 143. The gate insulating pattern GOX may be formed using at least one of physical vapor deposition (PVD), thermal chemical vapor deposition (thermal CVD), low pressure chemical vapor deposition (LP-CVD), plasma enhanced chemical vapor deposition (PE-CVD), and atomic layer deposition (ALD) techniques. However, example embodiments are not limited thereto.

After depositing the gate insulating pattern GOX, first and second word lines WL1 and WL2 may be formed on the side surfaces of the channel portion 310 of the active patterns AP1 and AP2.

Specifically, the forming of the first and second word lines WL1 and WL2 may include depositing a gate conductive film (not shown) conformally covering the gate insulating pattern GOX, and then performing an etching process on the gate conductive film.

During the etching process on the gate conductive film, the gate insulating pattern GOX may be used as an etching stop film, or the gate insulating pattern GOX may be over-etched to expose the gate capping pattern 143. Depending on the etching process on the gate conductive film, the first and second word lines WL1 and WL2 may have various shapes. For example, the upper surfaces of the first and second word lines WL1 and WL2 may be disposed at a lower level than the upper surfaces of the channel portion 310. In this case, at least a portion of the gate insulating pattern GOX may be exposed.

After the first and second word lines WL1 and WL2 are formed, impurities may be doped into the channel portion 310 through the exposed gate insulating pattern GOX by performing a gas phase doping (GPD) process or a plasma doping (PLAD) process, but various example embodiments are not limited thereto.

Next, the first gate separation pattern 153 and the second gate separation pattern 155 may be sequentially formed in the trench in which the first and second word lines WL1 and WL2 are formed. The first gate separation pattern 153 may be conformally formed. The first gate separation pattern 153 may include, for example, a silicon nitride (SiN), a silicon oxynitride (SiON), a silicon carbide (SiC), a silicon carbon nitride (SiCN), or a combination thereof. However, example embodiments are not limited thereto. The first gate separation pattern 153 may cover the surfaces of the word lines WL1 and WL2. Next, the second gate separation pattern 155 may be formed to fill the trench in which the first gate separation pattern 153 is formed. The second gate separation pattern 155 may be made of an insulating material different from that of the first gate separation pattern 153. The second gate separation pattern 155 and the first gate separation pattern 153 may cover the upper surface of the channel portion 310 and the upper surfaces of the back gate capping patterns 115.

Subsequently, a planarization process may be performed on the second gate separation pattern 155, the first gate separation pattern 153, and the gate insulating pattern GOX so that the upper surfaces of the back gate capping patterns 115 are exposed. Accordingly, the upper surface of the channel portion 310 may be exposed. In this case, as shown in FIG. 11, the upper surface of the channel portion 310, the upper surface of the second gate separation pattern 155, the upper surface of the first gate separation pattern 153, and the upper surface of the back gate capping patterns 115 may be disposed at the same level by the planarization process. That is, the upper surface of the channel portion 310, the upper surface of the second gate separation pattern 155, the upper surface of the first gate separation pattern 153, and the upper surface of the back gate capping patterns 115 may be disposed at substantially the same distance from the upper surface of the sub-substrate 100. However, various example embodiments are not limited thereto, and the upper surface of the channel portion 310, the upper surface of the second gate separation pattern 155, the upper surface of the first gate separation pattern 153, and the upper surface of the back gate capping patterns 115 may be disposed at different levels.

Hereinafter, for better comprehension and ease of description, the upper surface of the channel portion 310, the upper surface of the second gate separation pattern 155, the upper surface of the first gate separation pattern 153, and the upper surface of the back gate capping patterns 115 will be referred to as a first reference surface 10a, extending in the first direction (X direction) and the second direction (Y direction). In various example embodiments, the first reference surface 10a may be disposed on the same plane as one surface of the exposed channel portion 310.

Referring to FIG. 12 to FIG. 14, the pre-contact portion 310a may be formed through a selective epitaxial growth (SEG) using the channel portion 310 as a seed. The pre-contact portion 310a may be grown from the first reference surface 10a toward the third direction (Z direction). For example, the pre-contact portion (310a in FIG. 14) may grow along the third direction (Z direction) while covering one surface of the exposed channel portion 310, one surface of the gate insulating pattern GOX, and one surface of the back gate insulating pattern 113. The outer surface of the pre-contact portion 310a may have a convex shape, but example embodiments are not limited thereto. Accordingly, the pre-contact portion 310a may overlap the channel portion 310, the gate insulating pattern GOX, and the back gate insulating pattern 113 in the third direction (Z direction).

In various example embodiments, the pre-contact portion 310a may include a semiconductor material doped with impurities. Here, the semiconductor material may be silicon. The pre-contact portion 310a may include the same material as the channel portion 310. For example, the pre-contact portion 310a may include single crystal silicon doped with impurities. The process of forming the pre-contact portion 310a may be performed under a process temperature of about 430° C. or less. Under these conditions, the activation concentration of impurities included in the pre-contact portion 310a may increase. Here, the activation concentration may mean a concentration of an impurity capable of performing a dopant function by replacing a semiconductor material element with an impurity.

In the process of forming the pre-contact portion 310a, a pre-conductive pattern 161a may be formed together on one surface of the first gate separation pattern 153 and one surface of the second gate separation pattern 155 exposed at desired (and/or alternatively predetermined) intervals. That is, the pre-conductive pattern 161a may grow from the first reference surface 10a toward the third direction (Z direction). In this case, the pre-contact portion 310a may be formed by a selective epitaxial growth (SEG) using the first gate separation pattern 153 and the second gate separation pattern 155 as a seed. The pre-conductive pattern 161a may cover a side surface of the pre-contact portion 310a.

In various example embodiments, the pre-conductive pattern 161a may include a semiconductor material doped with impurities. The semiconductor material may be silicon. For example, the pre-conductive pattern 161a may include amorphous silicon (a-Si) doped with impurities. Here, the impurity may include phosphorus (P), but example embodiments are not limited thereto.

In various example embodiments, a height of the pre-conductive pattern 161a along the third direction (Z direction) may be substantially the same as that of the pre-contact portion 310a along the third direction (Z direction). Specifically, a growth rate of the pre-conductive pattern 161a in the third direction (Z direction) may be faster than that of the pre-contact portion 310a in the third direction (Z direction). Accordingly, as the pre-conductive pattern 161a grows, the height of the pre-conductive pattern 161a in the third direction (Z direction) may be equal to that of the pre-contact portion 310a in the third direction (Z direction). In this case, the upper surface 161a_U of the pre-conductive pattern 161a may be disposed at substantially the same level as one end of the pre-contact portion 310a. For example, as shown in FIG. 14, the upper surface 161a_U of the pre-conductive pattern 161a may be disposed at substantially the same level as the upper surface 320a_U of the pre-contact portion 320.

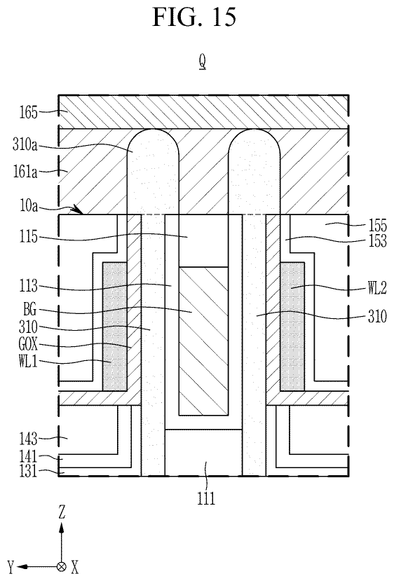

Referring to FIG. 15, the first conductive pattern 165 may be formed on the pre-conductive pattern 161a. In various example embodiments, the first conductive pattern 165 may include a conductive material. For example, the first conductive pattern 165 may include a conductive metal nitride (for example, a titanium nitride, a tantalum, or the like), a metal (for example, tungsten, titanium, tantalum, or the like), or a combination thereof. However, example embodiments are not limited thereto.

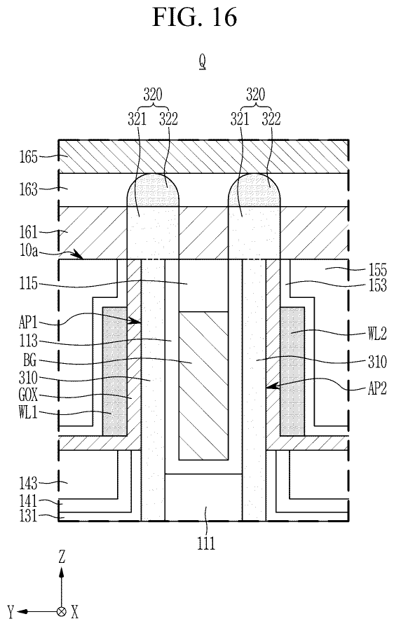

Referring to FIG. 16, through a silicide process, at least a portion of the pre-contact portion 310a and the pre-conductive pattern 161a are silicided to form the second conductive pattern 161 and the second portion 322 of the contact portion 320.

For example, at least a portion of the pre-conductive pattern 161a adjacent to the first conductive pattern 165 may be replaced with the second conductive pattern 161 through a silicide process. In addition, at least a portion of the pre-contact portion 310a adjacent to the first conductive pattern 165 may be replaced with the second portion 322 of the contact portion 320 through a silicide process. Accordingly, the first portion 321 and the second portion 322 of the contact portion 320 may be formed, and the second conductive pattern 161 and the third conductive pattern 163 may be formed. In various example embodiments, the silicide process may be performed through a heat treatment process.

The second portion 322 and the third conductive pattern 163 may include the same material. For example, the second portion 322 and the third conductive pattern 163 may include a metal-silicide material. For example, the second portion 322 may include titanium silicide, cobalt silicide, nickel silicide, or a combination thereof, but example embodiments are not limited thereto. The second portion 322 and the third conductive pattern 163 may be doped with impurities.

In this case, the activation concentration of the impurities doped into the second portion 322 may be smaller that than of the impurities doped into the third conductive pattern 163. This is because, as the second portion 322 includes single crystal silicon, the degree to which the doped impurities are activated may be relatively greater than that of the third conductive pattern 163 including amorphous silicon (a-Si). In addition, the activation concentration of the impurities doped into the second portion 322 may be smaller than that of the impurities doped into the first portion 321.

Meanwhile, the activation concentration of the impurities doped into the first portion 321 may be greater than that of the impurities doped into the second conductive pattern 161. For example, the activation concentration of the impurities doped into the first portion 321 may be greater than about 2×10²⁰ cm⁻³ and less than about 1×10²¹ cm⁻³. In addition, the activation concentration of the impurities doped into the first portion 321 may be greater than the activation concentration of the impurities doped into the third conductive pattern 163. This is because, as the first portion 321 includes single crystal silicon, the degree to which the doped impurities are activated may be relatively greater than that of the third conductive pattern 163 including amorphous silicon. In addition, the activation concentration of the impurities doped into the first portion 321 may be greater than the activation concentration of the impurities doped into the channel portion 310, but example embodiments are not limited thereto, and the activation concentration of the impurities doped into the first portion 321 may be less than or equal to the activation concentration of the impurities doped into the channel portion 310.

In FIG. 12 to FIG. 14, the first to third conductive patterns 163 are shown as flat, but various example embodiments are not limited thereto. For example, as in the embodiment of FIG. 5, at least a portion of the bit line BL may have a concave shape in a direction away from one surface of the sub-substrate 100.

FIG. 12 to FIG. 14 illustrate that the pre-contact portion 310a is formed using one surface of the channel portion 310 as a seed, but various example embodiments are not limited thereto. In some example embodiments, as in the embodiment of FIG. 9, the pre-contact portion 310a may be formed using the side surface and the upper surface of the channel portion 310 as a seed.

Referring to FIG. 17 to FIG. 19, first, a planarization process may be performed on the channel portion 310 of the active patterns AP1 and AP2, the second gate separation pattern 155, the first gate separation pattern 153, and the gate insulating pattern GOX. Subsequently, at least a portion of the second gate separation pattern 155, the first gate separation pattern 153, and the gate insulating pattern GOX may be recessed. In this case, the channel portion 310 of the active patterns AP1 and AP2 may not be recessed. Accordingly, at least a portion of the side surface of the channel portion 310 may be exposed.

Here, the exposed upper surface of the second gate separation pattern 155, the upper surface of the first gate separation pattern 153, and the upper surface of the back gate capping patterns 115 will be referred to as a second reference surface 10b, extending in the first direction (X direction) and the second direction (Y direction). In various example embodiments, the second reference surface 10b may be disposed at a lower level than the upper surface of the exposed channel portion 310. That is, the channel portion 310 may have a shape protruding from the second reference surface 10b along the third direction (Z direction).

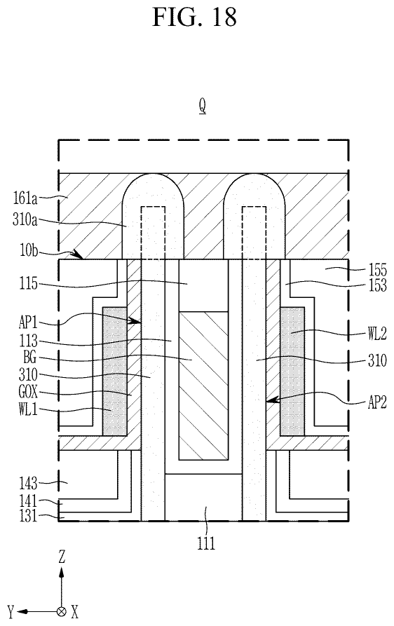

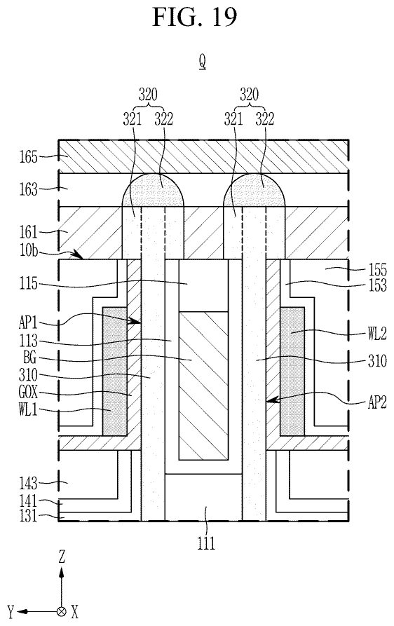

Subsequently, the pre-contact portion 310a may be formed through a selective epitaxial growth (SEG) using the exposed upper surface and side surface of the channel portion 310 as a seed. In this case, as shown in FIG. 18, the pre-conductive pattern 161a may be formed together on one surface of the first gate separation pattern 153 and one surface of the second gate separation pattern 155. Subsequently, as shown in FIG. 19, the first conductive pattern 165 may be formed on the pre-conductive pattern 161a, and the second conductive pattern 161 and the second portion 322 of the contact portion 320 may be formed through a silicide process. The description thereof is substantially the same as the description of the pre-contact portion 310a and the pre-conductive pattern 161a according to the embodiment of FIG. 12 to FIG. 14, so it will be omitted.

Referring to FIG. 20, first, the spacer insulating layer 171 may be formed on the bit lines BL, and a shielding pattern SP may be formed on the spacer insulating layer 171. Subsequently, the capping insulating layer 175 may be formed on the shielding pattern SP and the shielding insulating pattern 173. The capping insulating layer 175 may conformally cover the shielding pattern SP and the shielding insulating pattern 173, and the capping insulating layer 175 may include, for example, a silicon nitride film.

Subsequently, the flat insulating layer 180 may be formed on the capping insulating layer 175. The flat insulating layer 180 is an example of an insulating material having an etching selectivity with respect to the capping insulating layer 175, and the flat insulating layer 180 may include at least one of insulating materials and a silicon oxide layer formed using a spin-on-glass (SOG) technology. The flat insulating layer 180 may have a substantially flat upper surface.

Subsequently, the substrate 200 may be bonded onto the flat insulating layer 180. The substrate 200 may be bonded to the upper surface of the flat insulating layer 180 using an adhesive film. The substrate 200 may include, for example, single crystal silicon or glass (for example, quartz). However, example embodiments are not limited thereto.

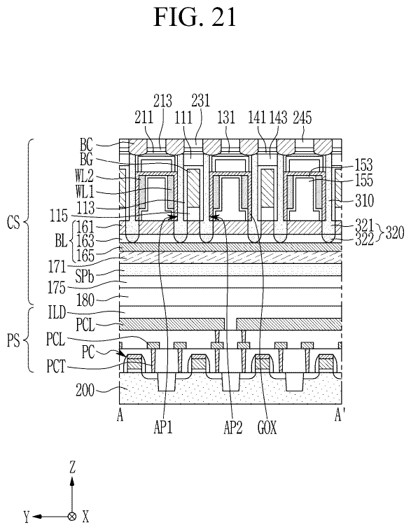

Referring to FIG. 21, after bonding the substrate 200, a rear lapping process of removing the sub-substrate 100 may be performed. The removing of the sub-substrate 100 may include sequentially performing a grinding process and a wet etching process to expose the buried insulating layer 101.

Next, the buried insulating layer 101 may be removed to expose the active patterns AP1 and AP2, the gate separation patterns 111, and the back gate insulating pattern 113. The buried insulating layer 101 may be etched by performing a wet or dry etching process, and the active patterns AP1 and AP2 may be used as an etching stop film during the etching process on the buried insulating layer 101.

Subsequently, the third and fourth etching stop films 211 and 213 may be sequentially formed. The third etching stop film 211 may include a silicon oxide, and may be deposited on the active patterns AP1 and AP2 and the gate separation patterns 111. The fourth etching stop film 213 may be made of a material having an etching selectivity with respect to the third etching stop film 211, and may include, for example, a silicon nitride. Subsequently, the interlayer insulating layer 231 may be formed, and at least a portion of the contact pads BC penetrating the interlayer insulating layer 231 to be connected to the first and second active patterns AP1 and AP2 may be formed.

In the forming of the contact pads BC, after forming holes exposing the first and second active patterns AP1 and AP2, respectively, by patterning the interlayer insulating layer 231, a conductive film filling the holes may be deposited, and the conductive layer may be planarized so that the upper surface of the interlayer insulating layer 231 is exposed.

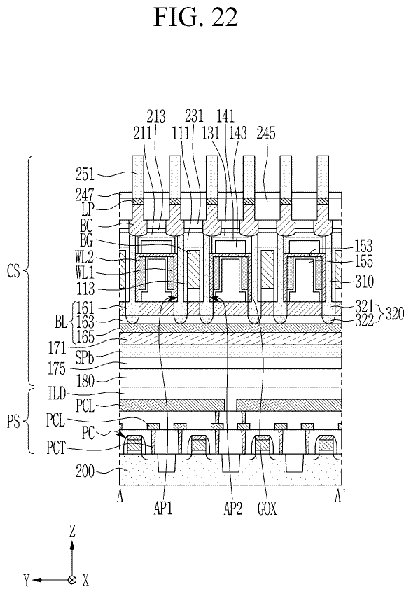

Referring to FIG. 22, the landing pad LPs connected to the contact pads BC, respectively, may be formed by patterning.

The forming of the landing pads LP may include forming a recess area by etching the interlayer insulating layer 231 between the landing pads LP and the contact pads BC using mask patterns, and forming the pad separation insulating pattern 245 by burying an insulating material in the recess area.

Here, some of the contact pads BC may be etched while the recess area is formed. The upper surface of the pad separation insulating pattern 245 may be substantially coplanar with the upper surfaces of the landing pads LP.

Subsequently, the fifth etching stop film 247 covering the upper surfaces of the landing pads LP may be formed. The fifth etching stop film 247 may cover the upper surface of the pad separation insulating pattern 245. The fifth etching stop film 247 may include an insulating material having an etching selectivity with respect to the pad separation insulating pattern 245.

Subsequently, the storage electrodes 251 penetrating the fifth etching stop film 247 and connected to the landing pads LP, respectively, may be formed. The storage electrodes 251 may include, for example, doped polysilicon, conductive metal nitride (for example, titanium, tantalum, or the like), metal (for example, tungsten, titanium, tantalum, or the like), conductive metal silicide, conductive metal oxide, or a combination thereof. However, example embodiments are not limited thereto.

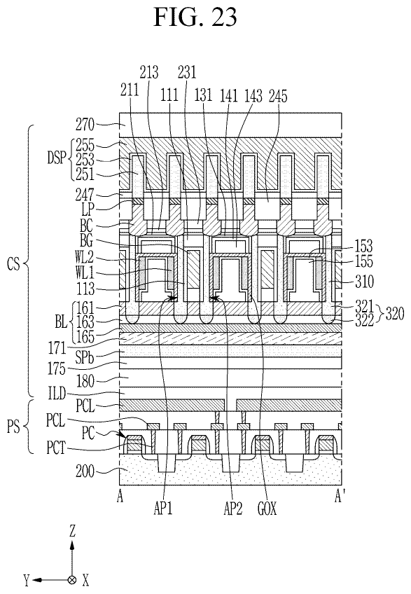

Referring to FIG. 23, the capacitor dielectric film 253 conformally covering the surfaces of the storage electrodes 251 may be formed. Subsequently, the data storage patterns DSP may be formed by forming the plate electrode 255 on the capacitor dielectric film 253. In addition, after forming the data storage patterns DSP, the upper insulating layer 270 may be formed on the data storage patterns DSP to form the semiconductor device according to the embodiment.

While various example embodiments have been described in connection with what is presently considered to be practical embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor device comprising:
a substrate;
a bit line on the substrate, extending in a first direction, including a first conductive pattern and a second conductive pattern on the first conductive pattern;
word lines extending on the bit line in a second direction intersecting the first direction; and
active patterns including
a channel portion between the word lines on the bit line, and
a contact portion extending from a lower surface of the channel portion to penetrate the second conductive pattern and electrically connected between the first conductive pattern and the channel portion.

2. The semiconductor device of claim 1, wherein
the second conductive pattern and the contact portion include silicon doped with impurities, and
an activation concentration of impurities doped into the contact portion is greater than that of impurities doped into the second conductive pattern.

3. The semiconductor device of claim 1, wherein
at least a portion of the contact portion is in contact with an upper surface of the first conductive pattern.

4. The semiconductor device of claim 1, wherein
the contact portion includes
a first portion extending from a lower surface of the channel portion toward the first conductive pattern, and
a second portion between the first portion and the first conductive pattern.

5. The semiconductor device of claim 4, wherein
the first portion includes silicon doped with impurities, and
an activation concentration of impurities doped in the first portion is greater than 2×10²⁰ cm⁻³ and less than 1×10²¹ cm⁻³.

6. The semiconductor device of claim 4, wherein
the first portion includes single crystal silicon, and the second conductive pattern includes amorphous silicon.

7. The semiconductor device of claim 4, wherein
the bit line further includes
a third conductive pattern between the first conductive pattern and the second conductive pattern, extending in the first direction, and
the third conductive pattern overlaps the second portion in the second direction.

8. The semiconductor device of claim 7, wherein
the third conductive pattern and the second portion include metal silicide doped with impurities, and
an activation concentration of impurities doped in the second portion is greater than that of impurities doped in the third conductive pattern.

9. The semiconductor device of claim 7, wherein
the first portion overlaps the second conductive pattern in the second direction.

10. The semiconductor device of claim 4, wherein
the first portion is integrally formed with the channel portion.

11. The semiconductor device of claim 1, wherein
a width of the contact portion in the second direction is greater than that of the channel portion in the second direction.

12. The semiconductor device of claim 11, further comprising
a gate insulating pattern between the active patterns and the word lines,
wherein the contact portion overlaps the gate insulating pattern in a third direction, the third direction being perpendicular to an upper surface of the substrate.

13. The semiconductor device of claim 1, further comprising
a back gate electrode extending in the second direction on the bit line and between the active patterns,
wherein the contact portion overlaps the back gate electrode in a third direction, the third direction being perpendicular to an upper surface of the substrate.

14. The semiconductor device of claim 13, further comprising
a back gate insulating pattern between the back gate electrode and the channel portion,
wherein an upper surface of the contact portion is in contact with the back gate insulating pattern.

15. A semiconductor device comprising:
a substrate;
a bit line on the substrate, extending in a first direction, including a first conductive pattern and a second conductive pattern on the first conductive pattern;
word lines extending on the bit line in a second direction intersecting the first direction; and
active patterns including a channel portion between the word lines on the bit line and a contact portion extending from a lower surface of the channel portion to penetrate the second conductive pattern,
wherein the second conductive pattern and the contact portion include silicon doped with impurities, and
an activation concentration of impurities doped into the contact portion is greater than that of impurities doped into the second conductive pattern.

16. The semiconductor device of claim 15, wherein
the contact portion includes
a first portion extending from a lower surface of the channel portion toward the first conductive pattern, and
a second portion between the first portion and the first conductive pattern, and
the first portion includes single crystal silicon, and the second conductive pattern includes amorphous silicon.

17. The semiconductor device of claim 16, wherein
an activation concentration of impurities doped in the first portion is greater than 2×10²⁰ cm⁻³ and less than 1×10²¹ cm⁻³.

18. The semiconductor device of claim 16, wherein
the bit line further includes
a third conductive pattern between the first conductive pattern and the second conductive pattern, extending in the first direction,
the third conductive pattern and the second portion include silicon doped impurities, and
an activation concentration of impurities doped in the second portion is greater than that of impurities doped in the third conductive pattern.

19. A semiconductor device comprising:
a substrate;
a bit line including
a first conductive pattern on the substrate extending in a first direction,
a second conductive pattern on the first conductive pattern, and
a third conductive pattern between the first conductive pattern and the second conductive pattern;
word lines extending on the bit line in a second direction intersecting the first direction;
active patterns including
a channel portion between the word lines on the bit line, and
a contact portion extending from a lower surface of the channel portion; and
a back gate electrode extending in the second direction on the bit line and between the active patterns,
wherein the contact portion includes
a first portion penetrating the second conductive pattern and including a semiconductor material doped with impurities,
a second portion between the first portion and the first conductive pattern and penetrating the third conductive pattern,
the first portion and the second conductive pattern include a semiconductor material doped impurities, and
an activation concentration of impurities doped into the first portion is greater than that of impurities doped into the second conductive pattern.

20. The semiconductor device of claim 19, further comprising
a back gate insulating pattern between the back gate electrode and the channel portion,
wherein an upper surface of the contact portion is in contact with the back gate insulating pattern.
